(19) United States
(12) Patent Application Publication
(10) Pub. No.: US 2026/0231526 A1
(43) Pub. Date: Aug. 6, 2026

(54) SEMICONDUCTOR STRUCTURE WITH REDUCED NANOSHEETS AND METHOD OF MANUFACTURING THE SAME

(71) Applicant: TAIWAN SEMICONDUCTOR MANUFACTURING COMPANY LTD., HSINCHU (TW)

(72) Inventors: HUNG-LI CHIANG, TAIPEI CITY (TW); WEI-CHENG LIN, TAICHUNG CITY (TW); JIANN-TYNG TZENG, HSINCHU (TW); YUNG-CHIN HOU, TAIPEI (TW)

(21) Appl. No.: 19/216,764

(22) Filed: May 23, 2025

Related U.S. Application Data
(60) Provisional application No. 63/755,160, filed on Feb. 6, 2025.

(51) Int. Cl. H10D 84/90; H10D 89/10

(52) U.S. Cl. CPC H10D 84/927; H10D 84/953; H10D 84/959; H10D 89/10

(57) ABSTRACT

The present disclosure provides a semiconductor structure including a first stack structure and a second stack structure. The first stack structure includes first metal gate structures and first channel layers alternatingly arranged with the first metal gate structures. The second stack structure is separated from the first stack structure and includes second metal gate structures and second channel layers alternatingly arranged with the second metal gates. The first stack structure has a first number of the first channel layers. The second stack structure has a second number of the second channel layers. The first number is different from the second number.

### CROSS-REFERENCE TO RELATED APPLICATION

This application claims the benefit of U.S. Provisional Application No. 63/755,160 filed Feb. 6, 2025, the entire disclosure of which is incorporated by reference herein.

### BACKGROUND

Semiconductor devices are used in a variety of electronic applications, such as personal computers, cellular phones, digital cameras, and other forms of electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in the minimum feature size, which allow more components to be integrated into a given area. However, as the minimum feature size is reduced, additional problems arise that should be addressed.

### BRIEF DESCRIPTION OF THE DRAWINGS

Aspects of embodiments of the present disclosure are best understood from the following detailed description when read with the accompanying figures. It should be noted that, in accordance with standard practice in the industry, various structures are not drawn to scale. In fact, dimensions of the various structures can be arbitrarily increased or reduced for clarity of discussion.

FIG. 1 is a flow diagram showing a method for forming a semiconductor structure, in accordance with some embodiments of the present disclosure.

FIGS. 2, 3, 4A, 4B, 5A, 5B, 6B, 7B, 7C, 8A, 8B, 9, 10A, 10B, 11A, 11B, 12 to 14, 15A to 15D and 16A to 16D are schematic cross-sectional views of sequential operations of the method in FIG. 1, in accordance with some embodiments of the present disclosure.

FIGS. 5C, 6A and 7A are schematic perspective views of some operations of the method in FIG. 1, in accordance with some embodiments of the present disclosure.

FIG. 17 is a flow diagram showing a method for continuing the method in FIG. 1, in accordance with some embodiments of the present disclosure.

FIGS. 18A, 18B, 19A, 19B, 20A, 20B, 21A, 21B, 22A, 22B to 22D, 23A, 23B, 24A, 24B, 25A, 25B, 26A, 26B, 27A, 27B, 28A, 28B, 29A, 29B, 30A, 30B, 31A, 31B and 32A to 32C are schematic cross-sectional views of sequential operations of the method in FIG. 17, in accordance with some embodiments of the present disclosure.

FIG. 33 is a schematic perspective view of a semiconductor structure formed using the method in FIG. 1 and the method in FIG. 17, in accordance with some embodiments of the present disclosure.

FIGS. 34A and 34B are simplified circuit diagrams of semiconductor devices including one or more of the semiconductor structures in FIG. 33, in accordance with some embodiments of the present disclosure.

FIGS. 35A to 35C are schematic views of chips or semiconductor structures including the semiconductor device in FIG. 34A or the semiconductor device in FIG. 34B, in accordance with some embodiments of the present disclosure.

FIG. 36 is a schematic view showing possible locations where parasitic capacitance may exist in a uniform-sheet nanosheet semiconductor structure similar to the semiconductor structure shown in FIG. 16C, in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 100 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to semiconductor structures (or integrated circuit structures) and methods of forming the same. More particularly, some embodiments of the present disclosure are related to semiconductor structures including asymmetric GAA stack structures including different numbers of sheets for reducing parasitic capacitance. Furthermore, electrical performance of such semiconductor structures is improved due to sheet reduction.

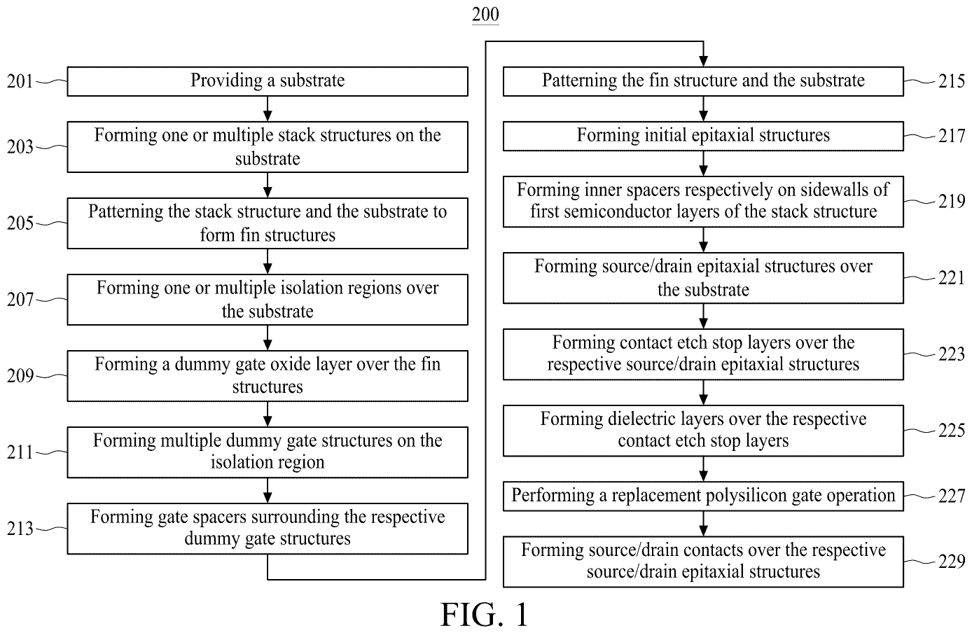

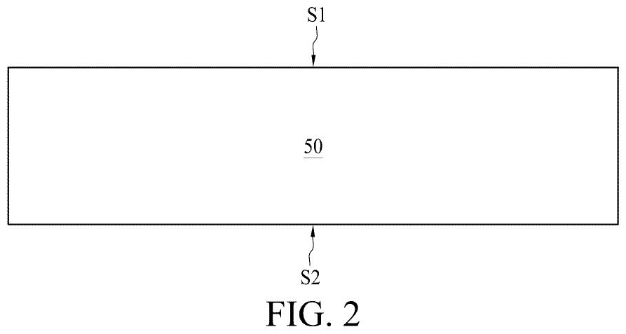

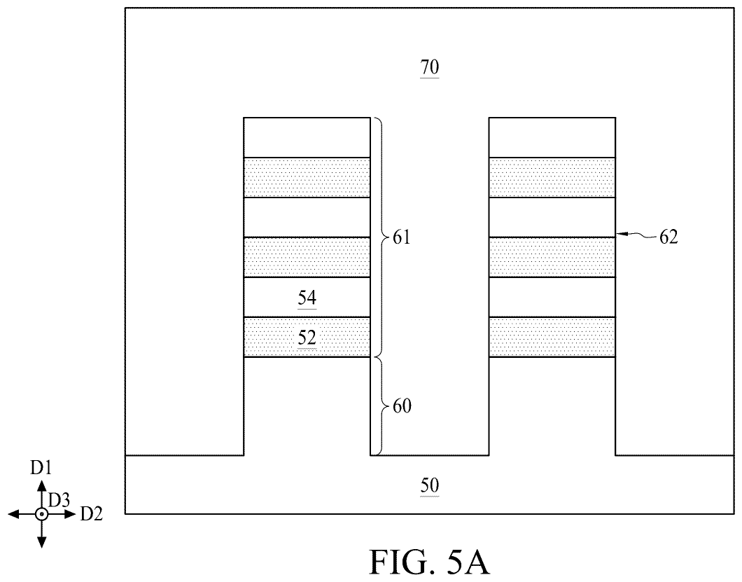

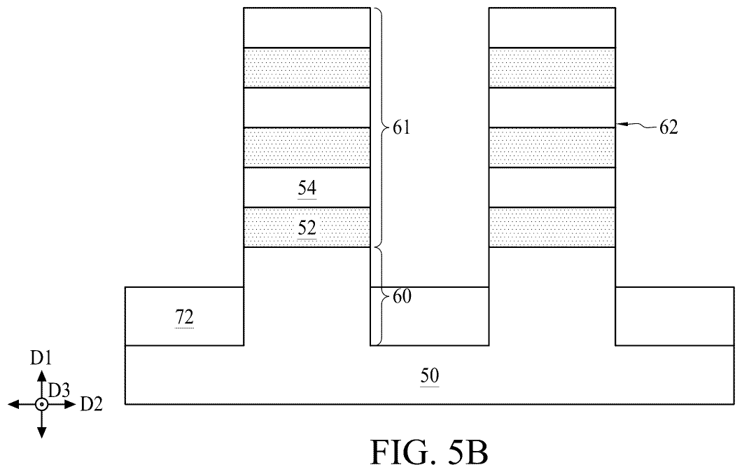

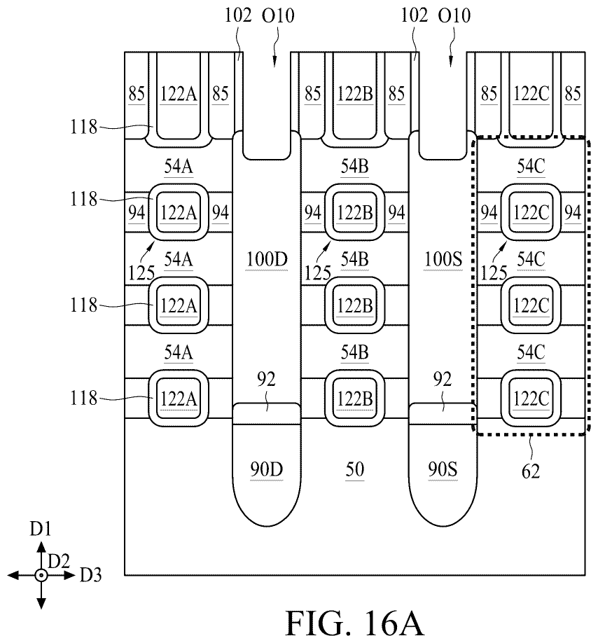

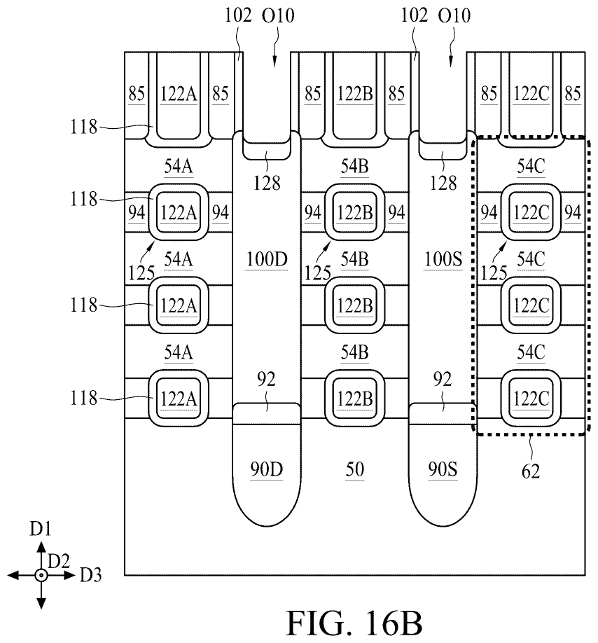

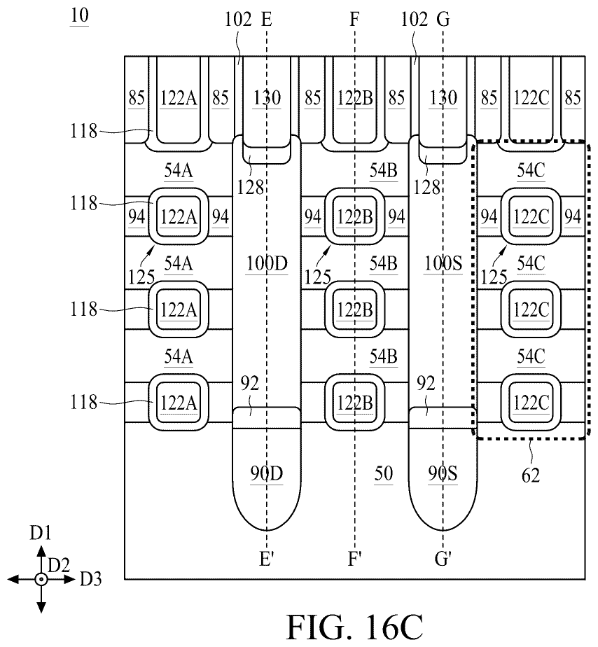

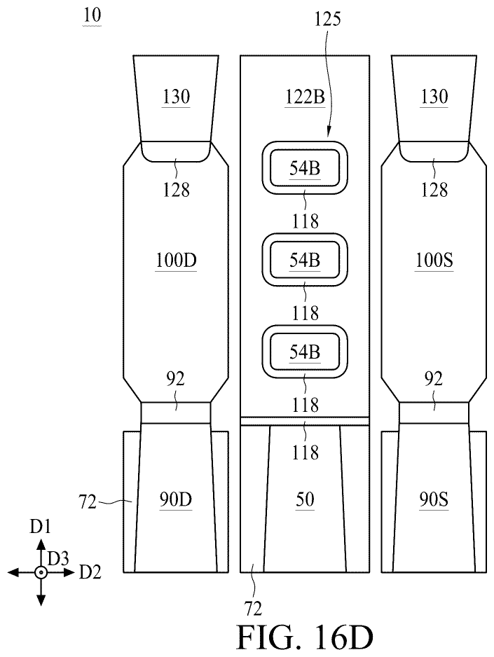

FIG. 1 is a flow diagram showing a method 200 for forming a semiconductor structure 10 in FIGS. 16C and 16D. FIGS. 2, 3, 4A, 4B, 5A, 5B, 6B, 7B, 7C, 8A, 8B, 9, 10A, 10B, 11A, 11B, 12 to 14, 15A to 15D and 16A to 16D are schematic cross-sectional views illustrating sequential operations of the method 200 in FIG. 1. The cross-sectional views may be taken along different directions and along different lines or planes. FIGS. 5C, 6A and 7A are schematic perspective views illustrating some operations of the method 200 in FIG. 1. The method 200 may be used to form a GAA transistor device. The method 200 includes a number of operations and the description and illustration are not deemed as a limitation to the sequence of the operations.

In operation 201 of FIG. 1, a substrate 50 is provided, as shown in FIG. 2. The substrate 50 has a first surface S1 (also referred to as a front side) and a second surface S2 (also referred to as a back side) opposite to the first surface S1. In some embodiments, the first surface S1 is used for forming transistors, but the present disclosure is not limited thereto. The substrate 50 may be a semiconductor substrate, such as a bulk semiconductor, a semiconductor-on-insulator (SOI) substrate, or the like, and may be doped (e.g., with a p-type or an n-type dopant) or undoped. The substrate 50 may be a wafer or a part of a wafer, such as a silicon (Si) wafer. Generally, an SOI substrate is a layer of a semiconductor material formed on an insulator layer. The insulator layer may be, for example, a buried oxide (BOX) layer, a silicon oxide (SiO₂) layer, or the like. The insulator layer is provided on a substrate, typically a silicon substrate or a glass substrate. Other substrates, such as a multi-layered or gradient substrate, may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, GaInAsP, the like, or a combination thereof.

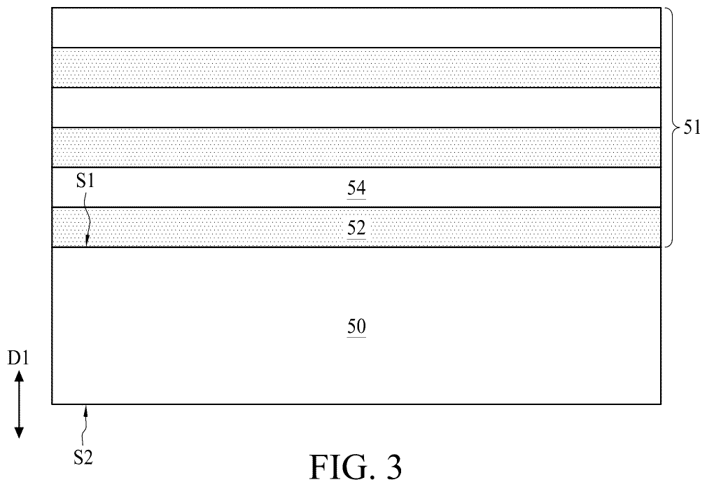

In operation 203 of FIG. 1, one or multiple stack structures 51 are formed on the substrate 50, as shown in FIG. 3. In some embodiments, multiple deposition and planarization operations are performed on the first surface S1 of the substrate 50 to form the stack structures 51. The stack structure 51 includes alternating first semiconductor layers 52 and second semiconductor layers 54. The first semiconductor layers 52 and the second semiconductor layers 54 are alternately formed over the substrate 50 along a first direction D1, which may be a thickness direction of the substrate 50. A number of layers of the first semiconductor layers 52 and the second semiconductor layers 54 illustrated in FIG. 3 are merely non-limiting examples. Other numbers of layers are also possible and are fully intended to be included within the scope of the present disclosure. In some embodiments, the first semiconductor layer 52 is formed of an epitaxial material appropriate for forming a channel region of, e.g., a p-type FET, such as silicon germanium (SiₓGe₁₋ₓ, where x can be in the range of 0 to 1). In some embodiments, the second semiconductor layer 54 is formed of an epitaxial material appropriate for forming a channel region of, e.g., an n-type or p-type FET, such as silicon. The stack structure 51 will be patterned to form channel regions of an NSFET (Nanosheet FET) in subsequent operations. In particular, the stack structure 51 will be patterned to form horizontal nanosheets, with the channel regions of the resulting NSFET including multiple horizontal nanosheets.

The stack structure 51 may be formed by an epitaxial growth operation, which may be performed in a growth chamber. In some embodiments, during the epitaxial growth operation, the growth chamber is cyclically exposed to a first set of precursors for selectively growing the first semiconductor layers 52, and then exposed to a second set of precursors for selectively growing the second semiconductor layers 54. The first set of precursors includes precursors for a first semiconductor material such as silicon germanium, and the second set of precursors includes precursors for a second semiconductor material such as silicon. In some embodiments, the first set of precursors includes a silicon precursor (e.g., silane) and a germanium precursor (e.g., a germane), and the second set of precursors includes the silicon precursor but omits the germanium precursor.

In some embodiments, the second semiconductor layers 54 serve as channel regions for a subsequently-formed semiconductor structure and the thickness is chosen based on device performance considerations. In some embodiments, the first semiconductor layers 52 will eventually be removed and serve to define a vertical distance between adjacent channel regions for a subsequently-formed nanosheet GAA devices and the thickness is chosen based on device performance considerations. Accordingly, the first semiconductor layer 52 may be referred to as a sacrificial layer, and the second semiconductor layer 54 may be referred to as a channel layer.

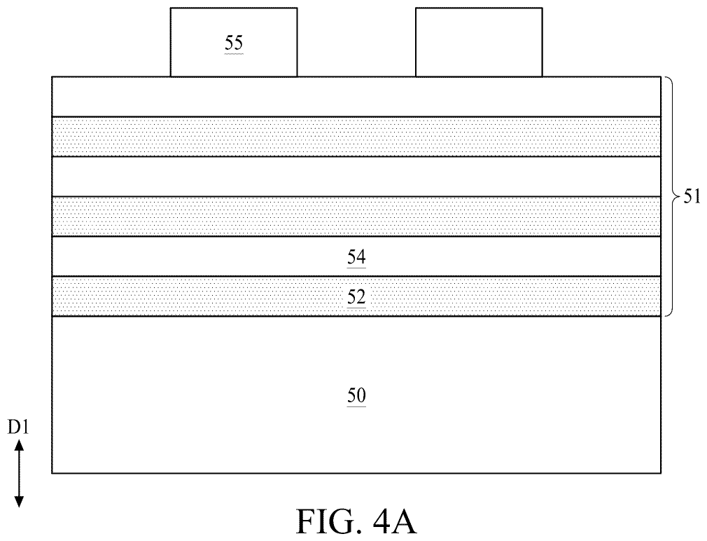

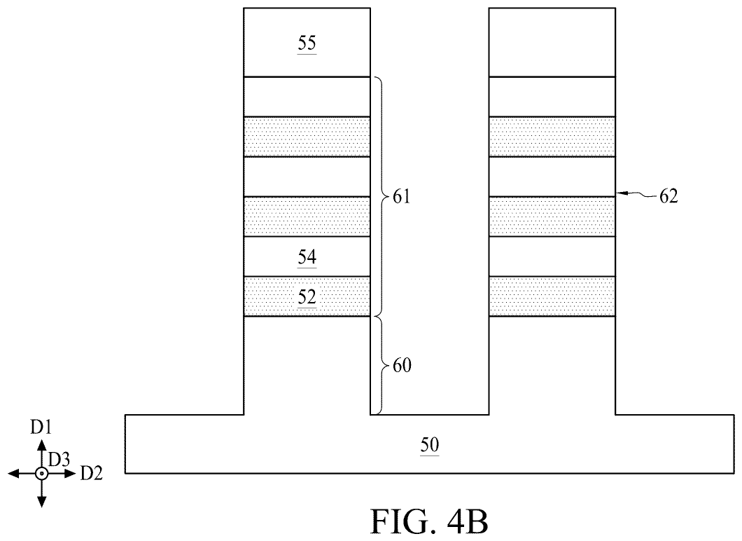

In operation 205 of FIG. 1, the stack structure 51 and the substrate 50 are patterned to form fin structures 62, as shown in FIGS. 4A and 4B.

Referring to FIG. 4A, a mask 55 is formed on the stack structure 51. The mask 55 may be a photoresist pattern or spacers formed using, for example, a self-aligned operation.

Referring to FIG. 4B, the substrate 50 and the stack structure 51 are patterned using a single-patterning operation, a double-patterning operation or a multi-patterning operation. Portions of the substrate 50 and the stack structure 51 are etched using the mask 55 as an etching mask. The etching may be any acceptable etching operation, such as a reactive ion etch (RIE), a neutral beam etch (NBE), the like, or a combination thereof. In some embodiments, the etching is an anisotropic etching operation. After the etching operation, multiple fins 60 are formed protruding from the remaining substrate 50. The fins 60 may be arranged along a second direction D2 perpendicular to the first direction D1. The fins 60 extend along a third direction D3 perpendicular to the first direction D1 and the second direction D2. A remaining portion of the stack structure 51 forms multiple fin-like stack structures 61 respectively disposed on one fin 60. In the illustrated embodiment, each of the fin-like stack structures 61 includes alternating first semiconductor layers 52 and second semiconductor layers 54. The fin 60 and the fin-like stack structure 61 may together be referred to as the fin structure 62. The mask 55 is then removed after the fin structure 62 is formed.

In operation 207 of FIG. 1, one or multiple isolation regions 72 are formed over the substrate 50, as shown in FIGS. 5A to 5C. Referring to FIG. 5A, an insulating material 70 is deposited over the substrate 50 using, for example, high density plasma chemical vapor deposition (HDP-CVD), flowable CVD (FCVD), or another suitable method. The insulating material 70 fills space between adjacent fins 60. The insulating material 70 may be silicon oxide, silicon nitride, silicon oxynitride (SiON), fluoride-doped silicate glass (FSG), phospho-silicate glass (PSG), boro-silicate glass (BSG), boron-doped phospho-silicate glass (BPSG), undoped silicate glass (USG), a low dielectric constant (low-k) dielectric (for example, k is between about 3 and about 5) such as carbon-doped oxide, an extremely low-k dielectric (for example, k is less 3) such as porous carbon-doped silicon dioxide, a polymer such as polyimide, the like, or a combination thereof.

Referring to FIGS. 5B and 5C, FIG. 5B is a schematic cross-sectional view along a direction same as that of FIG. 5A, and FIG. 5C is a schematic perspective view of the structure shown in FIG. 5B. As shown in FIGS. 5B and 5C, a planarization operation such as chemical mechanical polishing (CMP) is used remove a portion of the insulating material 70 over top surfaces of the topmost second semiconductor layers 54. Subsequently, the insulating material 70 is recessed using, for example, an etch-back operation until top portions of the fins 60 are exposed. The remaining insulating material 70 forms the isolation region 72. The isolation region 72 is disposed between adjacent fins 60. In some embodiments, the isolation region 72 is a shallow trench isolation (STI). In other embodiments, a top surface of the isolation region 72 is higher than or substantially level with a top surface of the fin 60 such that the fin 60 is completely surrounded by the isolation region 72. The isolation region 72 may have a substantially flat surface as illustrated, a convex surface, a concave surface or a combination thereof.

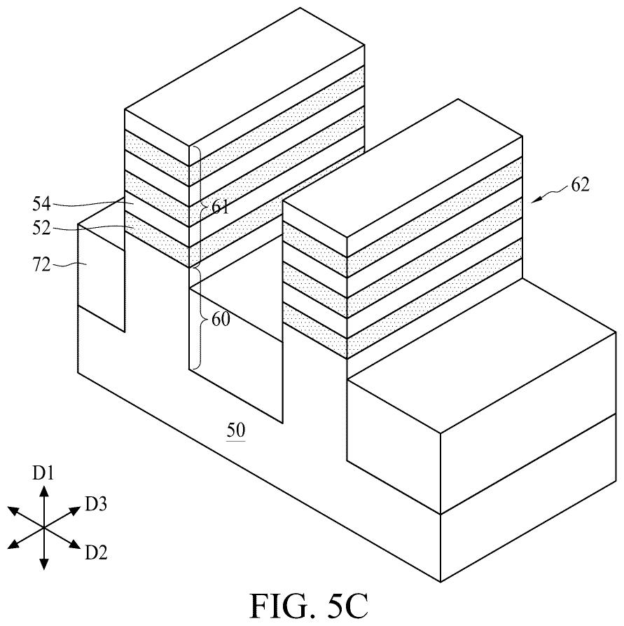

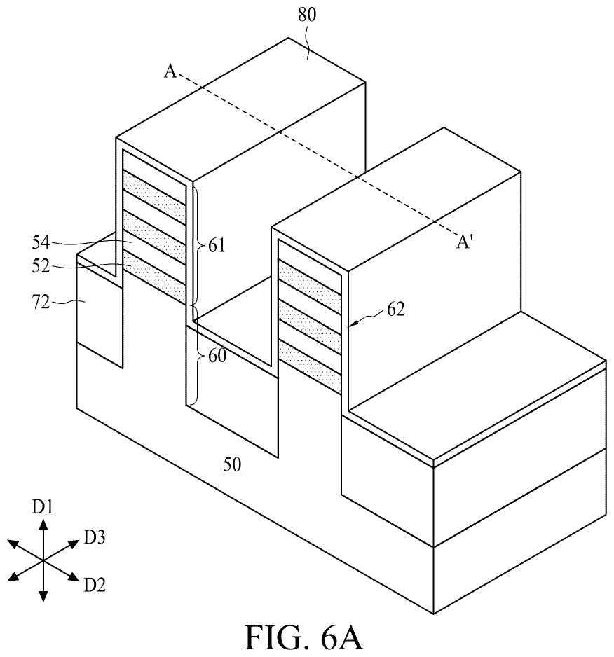

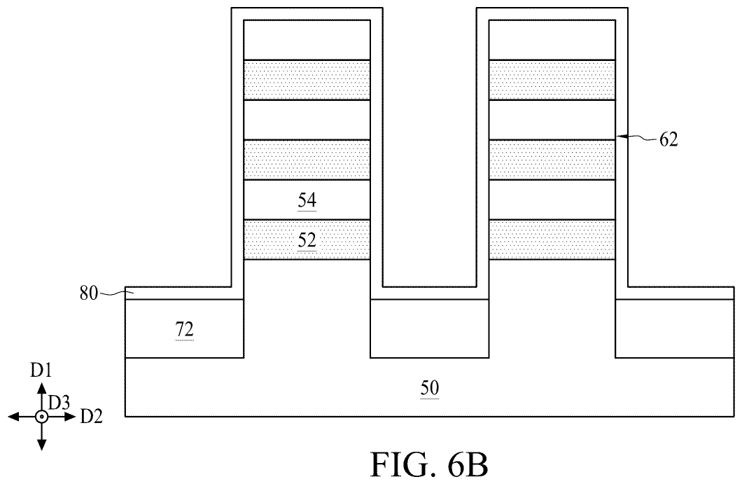

In operation 209 of FIG. 1, a dummy gate oxide layer 80 is formed over the fin structures 62, as shown in FIGS. 6A and 6B. FIG. 6B is a schematic cross-sectional view along cross-section A-A′ in FIG. 6A. In some embodiments, the dummy gate oxide layer 80 is formed by thermal oxidation, CVD, sputtering, atomic layer deposition (ALD), or another suitable method. In some embodiments, the dummy gate oxide layer 80 is formed of one or more suitable dielectric materials such as silicon oxide, silicon nitride, a low-k dielectric such as carbon-doped oxide, an extremely low-k dielectric such as porous carbon-doped silicon dioxide, a polymer such as polyimide, the like, or a combination thereof. In other embodiments, the dummy gate oxide layer 80 is made of a dielectric material having a high dielectric constant (k value) of, for example, greater than 9.0. The dielectric material includes metal oxides such as HfO₂, HfZrOₓ, HfSiOₓ, HfTiOₓ, HfAlOₓ, the like, or a combination thereof. The dummy gate oxide layer 80 may be conformally formed on the exposed fin structures 62, the exposed surface of the isolation region 72, and the top surface and sidewalls of the isolation region 72.

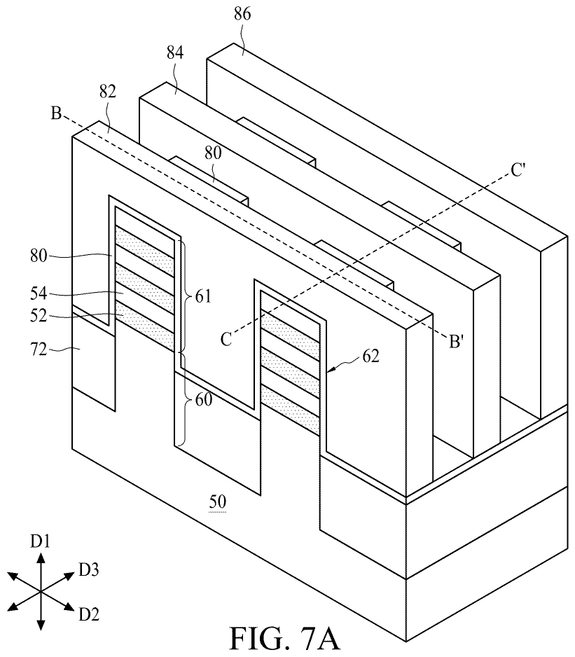

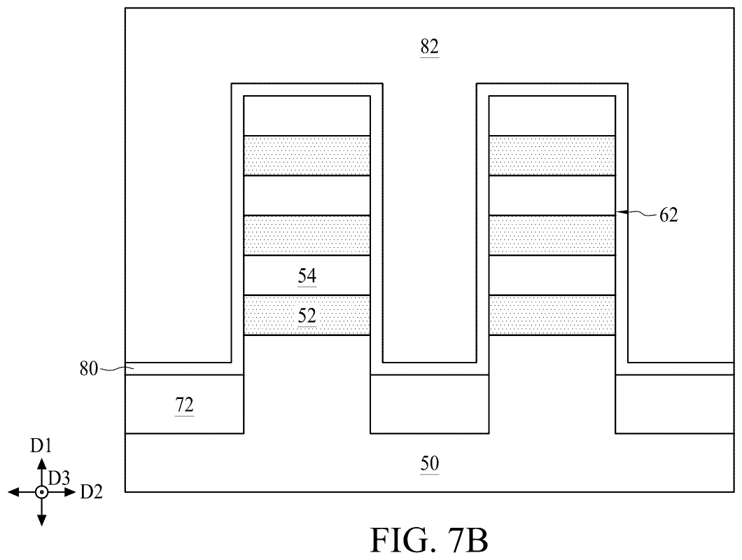

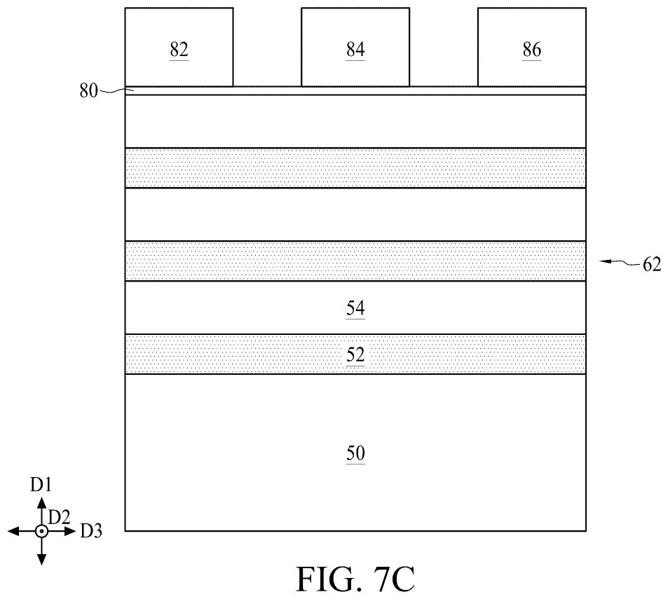

In operation 211 of FIG. 1, multiple dummy gate structures 82, 84 and 86 are formed on the isolation region 72, as shown in FIGS. 7A to 7C. FIG. 7B is a schematic cross-sectional view along cross-section B-B′ in FIG. 7A, and FIG. 7C is a schematic cross-sectional view along cross-section C-C′ in FIG. 7A. In some embodiments, the dummy gate structures 82, 84 and 86 are formed by physical vapor deposition (PVD), CVD, sputtering, or other suitable methods. The dummy gate structures 82, 84 and 86 are formed on the dummy gate oxide layer 80. Top surfaces of the dummy gate structures 82, 84 and 86 may be planarized after they are deposited. In some embodiments, the dummy gate structures 82, 84 and 86 are formed of amorphous silicon (a-Si), polycrystalline-silicon (polysilicon), poly-crystalline silicon-germanium (poly-SiGe), the like, or a combination thereof. The dummy gate structures 82, 84 and 86 are separated from each other and extend along the second direction D2. In some embodiments, the dummy gate structures 82, 84 and 86 extend along the second direction D2. The dummy gate structures 82, 84 and 86 wrap around different portions of multiple fin structures 62. The dummy gate structures 82, 84 and 86 may be referred to as sacrificial gate structures since they will be replaced with metal gate structures in subsequent operations.

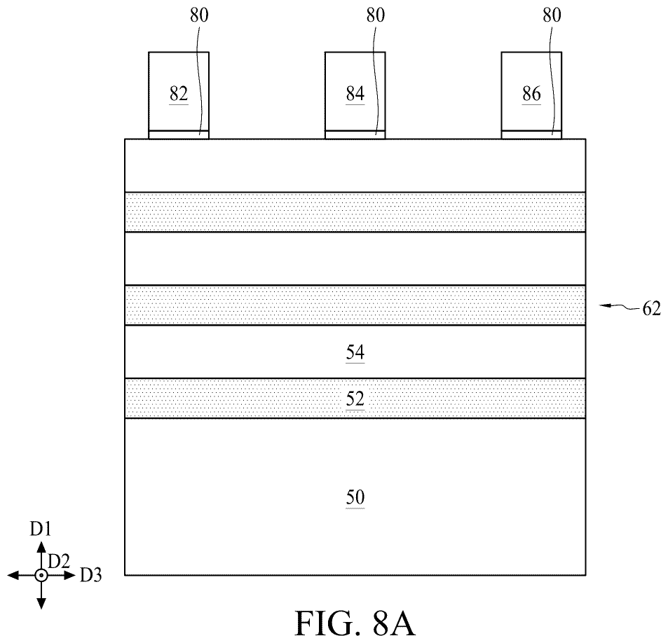

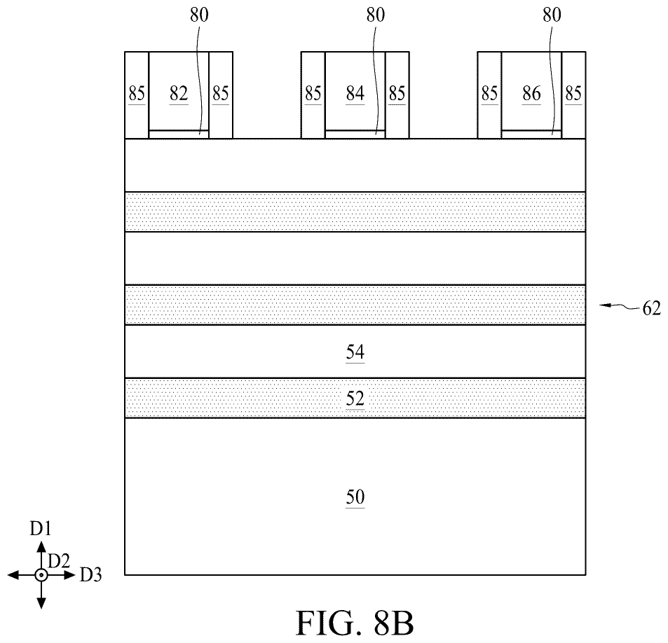

In operation 213 of FIG. 1, gate spacers 85 are formed surrounding the respective dummy gate structures 82, 84 and 86, as shown in FIGS. 8A and 8B. Referring to FIG. 8A, the dummy gate structures 82, 84 and 86 are each partially removed by an etching operation. Portions of the dummy gate oxide layer 80 are removed during the etching operation, thus forming multiple separated dummy gate oxide layers 80. Referring to FIG. 8B, a dielectric material such as silicon nitride is deposited over the dummy gate structures 82, 84 and 86. The dielectric material may be formed using ALD, CVD, sputtering, or another suitable method. Although not specifically illustrated, one or more photolithography operations and etching operations are used to pattern the dielectric material, thus forming the gate spacers 85. Sidewalls of the remaining dummy gate oxide layers 80 and sidewalls of the remaining dummy gate structures 82, 84 and 86 are respectively surrounded by the gate spacers 85. The gate spacer 85 may have a single-layer or a multilayer structure.

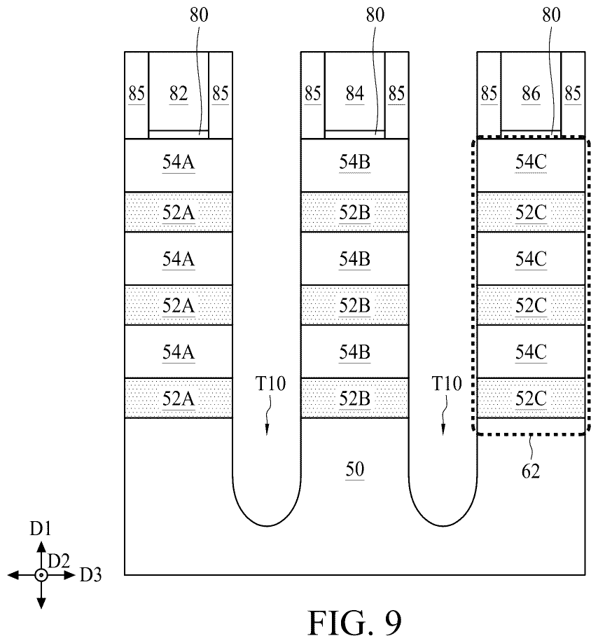

In operation 215 of FIG. 1, the fin structure 62 and the substrate 50 are patterned, as shown in FIG. 9. In some embodiments, portions of the fin structure 62 exposed by the gate spacers 85 and the dummy gate structures 82, 84 and 86 are removed using an anisotropic etching operation. In some embodiments, the anisotropic etching operation is a source/drain etching. The source/drain etching can be performed in a variety of ways. For example, the source/drain etching may be performed by a dry chemical etch with a plasma source and a reaction gas. The plasma source may be an inductively-coupled plasma (ICP) etch, a transformer-coupled plasma (TCP) etch, an electron cyclotron resonance (ECR) etch, a reactive ion etch (RIE) or the like, and the reaction gas may be a fluorine-based gas (such as SF₆, CH₂F₂, CH₃F, CHF₃, or the like), chloride (Cl₂), hydrogen bromide (HBr), oxygen (O₂), the like, or a combination thereof. In other embodiments, the source/drain etching may be performed by a wet chemical etch, such as ammonium peroxide mixture (APM), NH₄OH, tetramethylammonium hydroxide (TMAH), the like, or a combination thereof. In yet other embodiments, the source/drain etching may be performed using a combination of a dry chemical etch and a wet chemical etch.

In some embodiments, the anisotropic etching operation selectively removes portions of the fin structure 62 without substantially consuming the gate spacers 85, the dummy gate oxide layers 80 and the dummy gate structures 82, 84 and 86. During the anisotropic etching operation, portions of the fin structure 62 are removed. The first semiconductor layers 52 become separated first semiconductor layers 52A, 52B and 52C, and the second semiconductor layers 54 become separated second semiconductor layers 54A, 54B and 54C. In some embodiments, the anisotropic etching operation also recesses portions of the substrate 50 exposed by the first semiconductor layers 52A, 52B and 52C and the second semiconductor layers 54A, 54B and 54C. In other embodiments, an etching operation other than the anisotropic etching operation for etching the fin structure 62 is used to recess the substrate 50. Multiple recesses T10 are formed extending into the substrate 50. The recesses T10 may have round bottom profiles, but can in practice have various profiles based on the etching operation implemented.

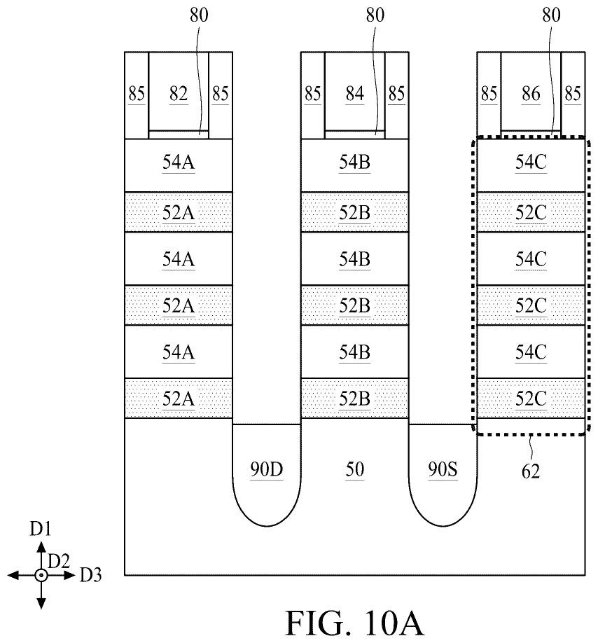

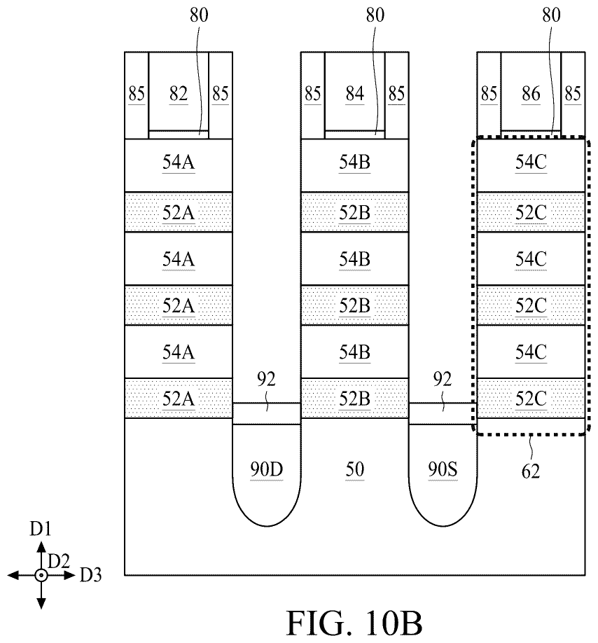

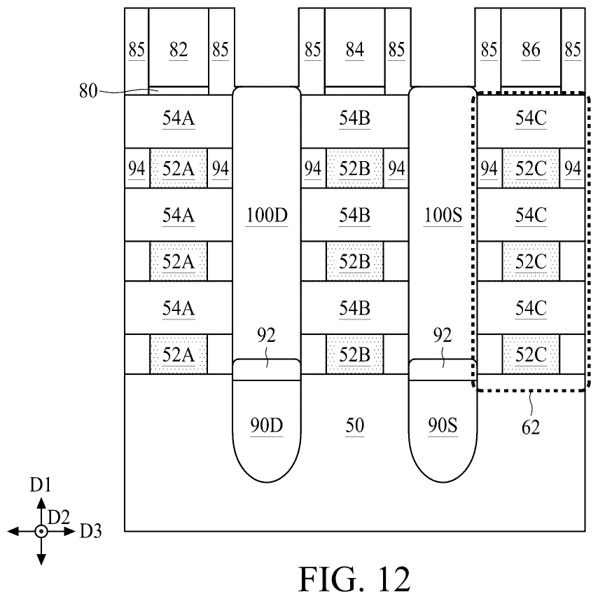

In operation 217 of FIG. 1, initial epitaxial structures 90S and 90D are respectively formed in the recesses T10, as shown in FIGS. 10A and 10B. Referring to FIG. 10A, an epitaxial growth operation is formed on silicon exposed by the recesses T10 to form the initial epitaxial structures 90S/90D. In some embodiments, the initial epitaxial structures 90S/90D function as initial layers for subsequently-formed source/drain epitaxial structures 100S and 100D (see FIG. 12). In some embodiments, the initial epitaxial structures 90S/90D are epitaxially grown to a degree that each of the recesses T10 is substantially filled or partially filled.

Referring to FIG. 10B, in some embodiments, dielectric layers 92 are respectively formed on the initial epitaxial structures 90S/90D. In some embodiments, the dielectric layers 92 are formed by CVD, ALD, or another suitable method. In some embodiments, the dielectric layers 92 are formed of a low-k dielectric, such as SiO₂, SiN, SiCN, or SiOCN. The dielectric layers 92 may be used to respectively protect the subsequently-formed source/drain epitaxial structures 100S/100D from, for example, an etching operation. In other embodiments, the dielectric layers 92 are absent. That is, the formation of the dielectric layers 92 is optional.

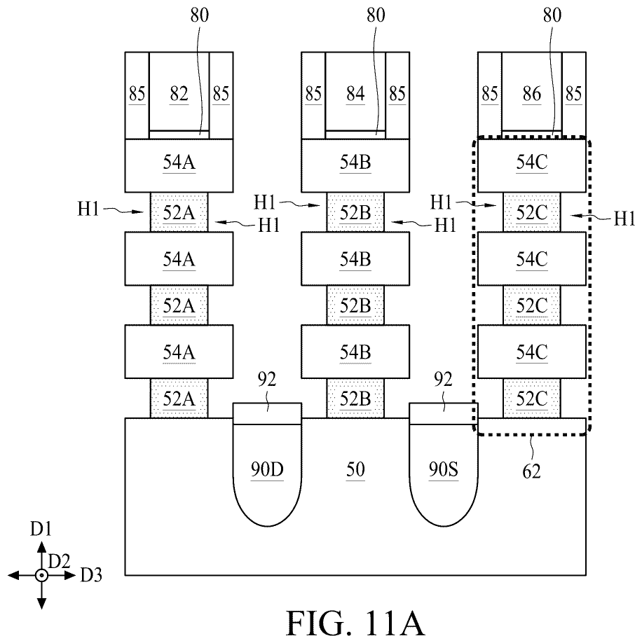

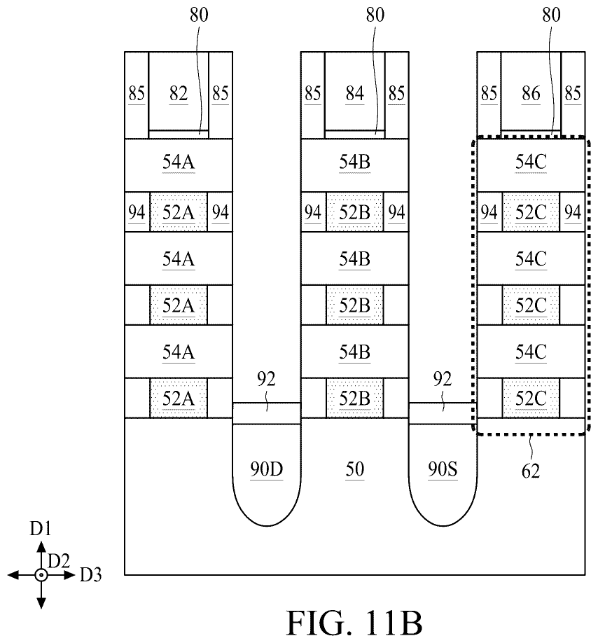

In operation 219 of FIG. 1, inner spacers 94 are respectively formed on sidewalls of the first semiconductor layers 52A, the first semiconductor layers 52B and the first semiconductor layers 52C, as shown in FIGS. 11A and 11B. Referring to FIG. 11A, in some embodiments, one or more etching operations are used to remove portions of the first semiconductor layer 52A, portions of the first semiconductor layer 52B and portions of the first semiconductor layer 52C. The first semiconductor layers 52A, 52B and 52C are horizontally recessed using a selective etching, resulting in multiple openings H1 each on an outer side of the second semiconductor layers 54A, 54B and 54C. By way of example and not limitation, the first semiconductor layers 52A, 52B and 52C are made of silicon-germanium and the second semiconductor layers 54A, 54B and 54C are made of silicon, allowing for the selective etching of the first semiconductor layers 52A, 52B and 52C. In some embodiments, the selective etching includes using an ammonia hydroxide-hydrogen peroxide-water mixture that etches silicon-germanium at a rate faster than a rate at which it etches silicon. As a result, the second semiconductor layers 54A, 54B and 54C laterally extend past opposite end surfaces of the first semiconductor layers 52A, 52B and 52C, respectively.

Referring to FIG. 11B, a dielectric material is respectively formed on sidewalls of the remaining first semiconductor layers 52A, sidewalls of the remaining first semiconductor layers 52B and sidewalls of the remaining first semiconductor layers 52C. In some embodiments, the dielectric material includes a silicon nitride-based material, such as SiN, silicon oxynitride, silicon oxycarbonitride (SiOCN), silicon carbon nitride (SiCN), the like, or a combination thereof. The dielectric material may be formed using ALD, CVD, or another suitable method.

After each of the openings H1 is filled with the dielectric material, one or more etching operations are used to trim the dielectric material outside sidewalls of the second semiconductor layers 54A, 54B and 54C, thus forming the inner spacers 94.

In operation 221 of FIG. 1, source/drain epitaxial structures 100S/100D are formed over the substrate 50, as shown in FIG. 12. In some embodiments, the source/drain epitaxial structures 100S/100D are formed using metal-organic chemical vapor deposition (MOCVD), molecular beam epitaxy (MBE), liquid phase epitaxy (LPE), vapor phase epitaxy (VPE), selective epitaxial growth (SEG), or other suitable methods. In embodiments where the dielectric layers 92 are present, the source/drain epitaxial structures 100S/100D are laterally formed from the second semiconductor layers 54A, 54B and 54C. In embodiments where the dielectric layer 92 is absent, the source/drain epitaxial structures 100S/100D are laterally formed from the second semiconductor layers 54A, 54B and 54C and upwardly formed from the initial epitaxial structures 90S/90D. In some embodiments, the source/drain epitaxial structures 100S/100D are formed of a material including silicon germanium. The material gradually becomes larger in size and fills spaces between adjacent fin structures 62. The source/drain epitaxial structures 100S/100D may have various profiles. The profile of the source/drain epitaxial structures 100S/100D shown in FIG. 12 and following figures is merely illustrative. The source/drain epitaxial structures 100S/100D may have surfaces raised from respective end surfaces of the second semiconductor layers 54A, 54B and 54C and may have multiple facets.

The source/drain epitaxial structures 100S/100D may be in-situ doped during the epitaxial growth operation by introducing doping species including p-type dopants such as boron or BF₂, or n-type dopants such as phosphorus or arsenic. If the source/drain epitaxial structures 100S/100D are not in-situ doped, an implantation operation is performed to dope the source/drain epitaxial structures 100S/100D. In some embodiments, the source/drain epitaxial structures 100S/100D in an n-type transistor include SiP, while those in a p-type transistor include SiGeB, GeSnB, and/or SiGeSnB. After the source/drain epitaxial structures 100S/100D are formed, an annealing operation can be performed to activate the p-type dopants or n-type dopants in the source/drain epitaxial structures 100S/100D. The annealing operation may be, for example, a rapid thermal anneal (RTA), a laser anneal, a millisecond thermal anneal (MSA), or the like.

In some embodiments, a lattice constant of the source/drain epitaxial structures 100S/100D is different from a lattice constant of the second semiconductor layers 54A, 54B and 54C, such that channel regions in the second semiconductor layers 54A, 54B and 54C can be strained or stressed by the source/drain epitaxial structures 100S/100D to improve mobility of carriers such as electrons.

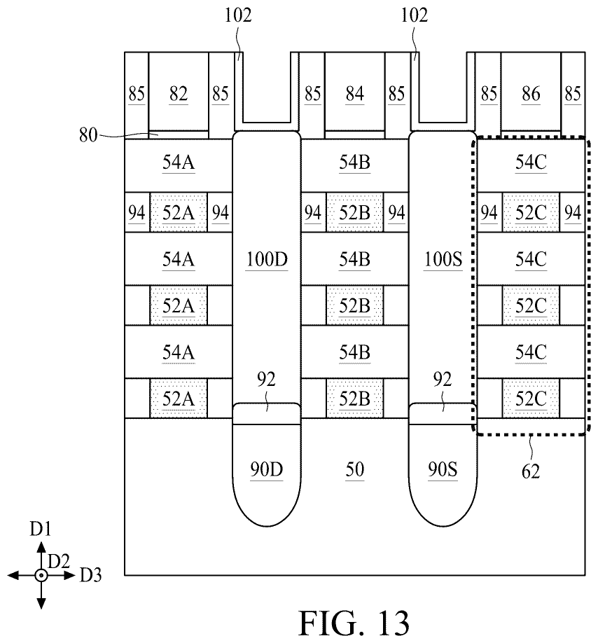

In operation 223 of FIG. 1, contact etch stop layers (CESLs) 102 are formed over the respective source/drain epitaxial structures 100S/100D, as shown in FIG. 13. In some embodiments, a dielectric material such as SiN, SiON, SiCN, SiOCN or a combination thereof is conformally deposited on the source/drain epitaxial structures 100S/100D, the gate spacers 85 and the dummy gate structures 82, 84 and 86. The dielectric material may be formed using plasma-enhanced CVD (PECVD), low-pressure CVD (LPCVD), ALD, or other suitable methods. In some embodiments, the contact etch stop layer 102 can be a stressed layer.

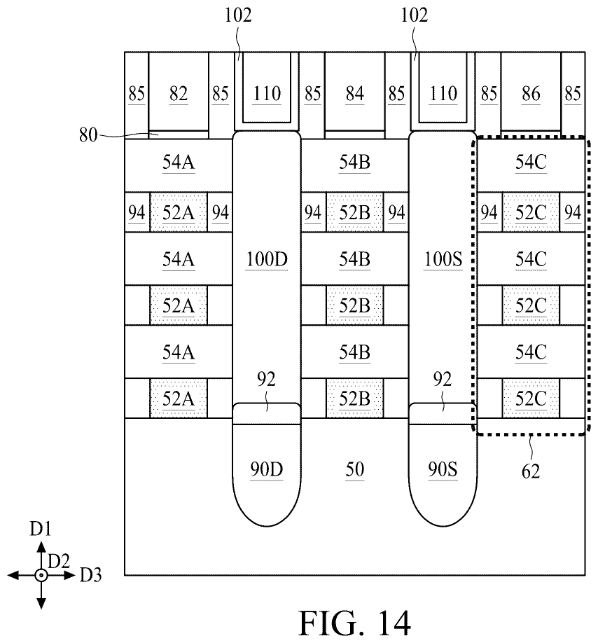

In operation 225 of FIG. 1, dielectric layers 110 are formed over the respective contact etch stop layers 102, as shown in FIG. 14. In some embodiments, a dielectric material such as silicon oxide, silicon nitride, PSG, BSG, BPSG, USG or a combination thereof is deposited on the contact etch stop layers 102, the gate spacers 85 and the dummy gate structures 82, 84 and 86. The dielectric material may be formed using CVD, PECVD, FCVD, spin coating, or another suitable method. Other insulating materials, formed by any acceptable method, may be used. A planarization operation such as CMP may be used to remove excess portions of the dielectric material of the contact etch stop layer 102 and the dielectric layer 110 over top surfaces of the gate spacers 85 and the dummy gate structures 82, 84 and 86, thus forming the dielectric layers 110. The top surfaces of the dummy gate structures 82, 84 and 86 are exposed through the dielectric layers 110 and level with the top surfaces of the contact etch stop layer 102 and the dielectric layer 110.

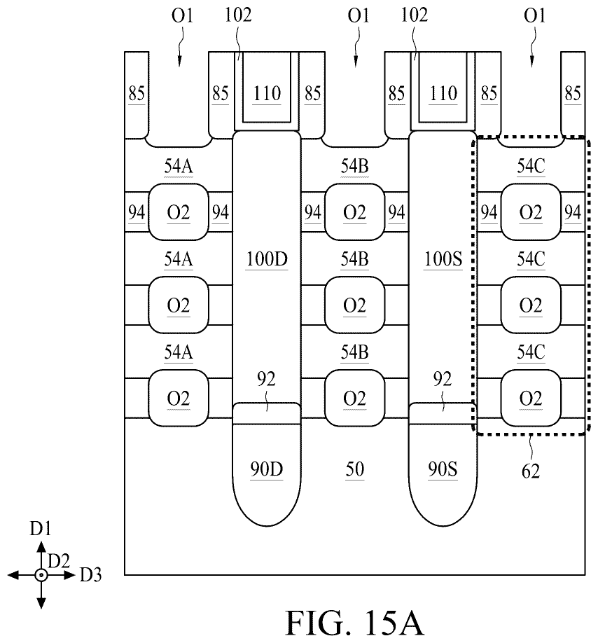

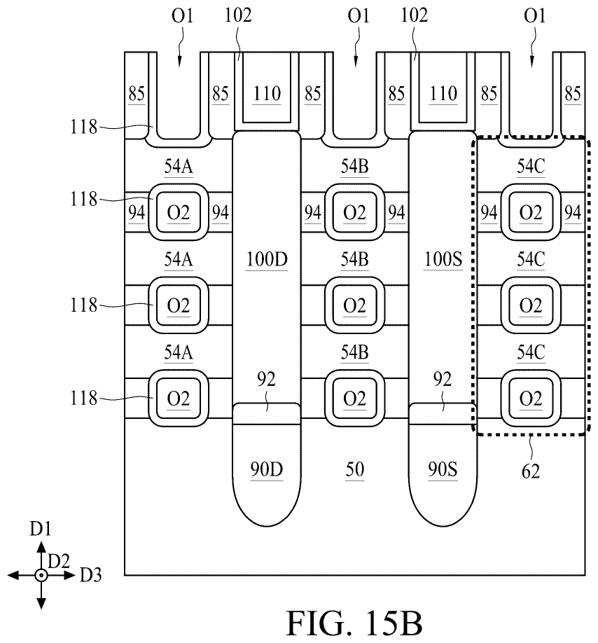

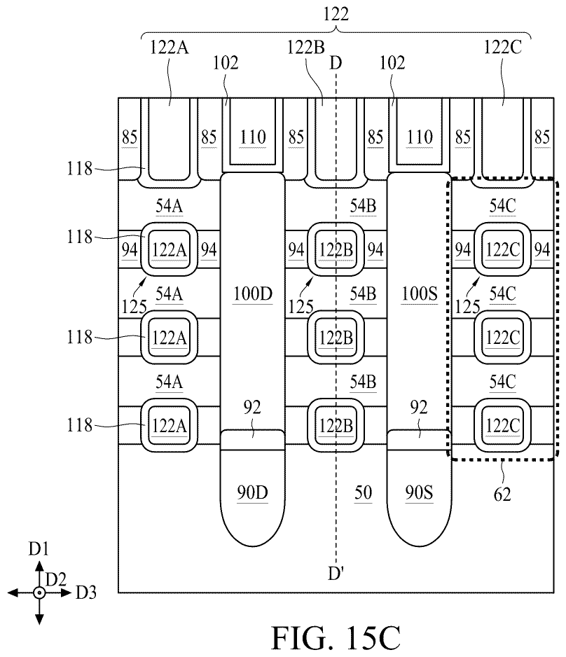

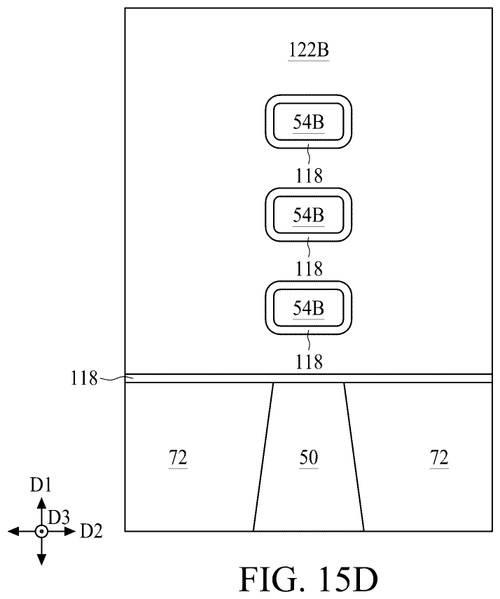

In operation 227 of FIG. 1, a replacement polysilicon gate (RPG) operation is performed, as shown in FIGS. 15A to 15D. Referring to FIG. 15A, one or more etching operation are used to remove the dummy gate structures 82, 84 and 86 and the dummy gate oxide layers 80. After multiple gate trenches O1 between the gate spacers 85 are formed, another etching operation is used to remove the first semiconductor layers 52A, 52B and 52C. The etching operation may be referred to as a silicon removal operation. In some embodiments, the silicon removal operation includes using a solution selective to silicon. For example, TMAH may be used in such operation. In some embodiments, the silicon removal operation selectively etches the first semiconductor layers 52A, 52B and 52C without substantially consuming the second semiconductor layers 54A, 54B and 54C. After the first semiconductor layers 52A, 52B and 52C are removed, multiple openings O2 are formed between the inner spacers 94. At this stage, the second semiconductor layers 54A, 54B and 54C become horizontal nanosheets suspended over the substrate 50. The second semiconductor layers 54A, 54B and 54C are between the source/drain epitaxial structures 100S/100D and other pairs of source/drain epitaxial structures (not shown). The second semiconductor layers 54A, 54B and 54C can be interchangeably referred to as nanostructures (or alternatively, nanowire structures, nanosheet structures, etc., depending on their geometry). The nanosheet structures may be collectively referred to as channel regions.

Referring to FIG. 15B, gate dielectric layers 118 are conformally deposited on exposed portions of the second semiconductor layers 54A, 54B and 54C and in the openings O2 formed by the removal of the first semiconductor layers 52A, 52B and 52C. Furthermore, some of the gate dielectric layers 118 are formed in the trenches O1 between the gate spacers 85. The gate dielectric layers 118 are formed using thermal oxidation, ALD, CVD, molecular-beam deposition (MBD), or another suitable method. In some embodiments, the gate dielectric layers 118 are formed of a high-k dielectric (a material with a k value greater than about 7.0) such as hafnium oxide (HfO₂), zirconium oxide (ZrO₂), lanthanum oxide (La₂O₃), hafnium aluminum oxide (HfAlO₂), hafnium silicon oxide (HfSiO₂), aluminum oxide (Al₂O₃), the like, or a combination thereof. In some embodiments, the gate dielectric layers 118 cover sidewalls of the inner spacers 94 and sidewalls of the second semiconductor layers 54A, 54B and 54C, as shown in FIG. 15B.

Referring to FIG. 15C, one or more conductive materials are deposited over the substrate 50 to form a gate layer 122. The conductive material is formed using sputtering, PVD, CVD, ALD, or another suitable method. The conductive material is deposited into the openings O1 and O2 and conformally formed over the gate dielectric layers 118.

Referring to FIG. 15D, FIG. 15D is a cross-sectional view along cross-section D-D′ in FIG. 15C. In some embodiments, the gate layer 122 includes multiple gate electrodes 122A, 122B and 122C parallel to each other, although FIG. 15D shows only the gate electrode 122B. The second semiconductor layers 54A, 54B and 54C are respectively wrapped around by the gate electrodes 122A, 122B and 122C. In some embodiments, the gate electrodes 122A, 122B and 122C are multi-layered structures. Each of the gate electrodes 122A, 122B and 122C may include a plurality of layers such as barrier layers, work function layers and conductive layers. For example, the barrier layer may be conformally formed on the gate dielectric layer 118. The barrier layer is made of titanium (Ti), tantalum (Ta), titanium nitride (TiN), tantalum nitride (TaN), the like, or a combination thereof. The work function layer may be conformally formed on the barrier layer. Exemplary p-type work function materials (which may also be referred to as p-type work function metals) include TiN, TaN, Ru, Mo, WN, ZrSi₂, MoSi₂, TaSi₂, NiSi₂, WN, other suitable p-type work function materials, or a combination thereof. Exemplary n-type work function materials (which may also be referred to as n-type work function metals) include Ti, Ag, TaAl, TaAlC, TiAlN, TaC, TaCN, TaSiN, Mn, Zr, other suitable n-type work function materials, or a combination thereof. The conductive layer may be formed on the work function layer and fill the space left by the work function layer. The conductive layer is made of W, Cu, Co, Al, Ni, Ta, Ti, Mo, Pd, Pt, Ru, Ir, Ag, Au, the like, or a combination thereof.

The gate electrodes 122A, 122B and 122C and their respective gate dielectric layers 118 may be collectively referred to as gate structures 125. The gate structures 125 and the second semiconductor layers 54A, 54B and 54C (i.e., the nanosheets) are alternately arranged along the first direction D1. In some embodiments, the inner spacers 94 are disposed on opposite sides of one gate structure 125.

In operation 229 of FIG. 1, source/drain contacts 130 are formed over the respective source/drain epitaxial structures 100S/100D, as shown in FIGS. 16A to 16D. Referring to FIG. 16A, an etching operation is used to remove portions of the dielectric layers 110 and the contact etch stop layers 102 to form openings O10 exposing the underlying source/drain epitaxial structures 100S/100D. Despite a presence of the contact etch stop layers 102, portions of the source/drain epitaxial structures 100S/100D may be consumed during the etching operation.

Referring to FIG. 16B, a silicidation operation is performed on the source/drain epitaxial structures 100S/100D. In some embodiments, the silicidation operation converts upper portions of the source/drain epitaxial structures 100S/100D into metal silicides 128. The metal silicides 128 are used to improve adhesion or electrical conductivity between the source/drain epitaxial structures 100S/100D and subsequently-deposited conductive materials.

Referring to FIG. 16C, one or more conductive materials are deposited on the metal silicides 128 and the source/drain epitaxial structures 100S/100D to form the source/drain contacts 130. The conductive material includes W, Cu, Co, Al, Ni, Ta, Ti, Mo, Pd, Pt, Ru, Ir, Ag, Au, the like, or a combination thereof. The source/drain contact 130 penetrates the dielectric layer 110 and the contact etch stop layer 102, and extends to the source/drain epitaxial structure 100S/100D. The source/drain contacts 130 are electrically coupled to the source/drain epitaxial structures 100S/100D. The source/drain contact 130 formed over the source epitaxial structure 100S may be referred to as a source contact 130, and the source/drain contact 130 formed over the drain epitaxial structure 100D may be referred to as a drain contact 130. At this stage, the semiconductor structure 10 is formed.

FIG. 16D is a combined cross-sectional view along three parallel cross-sections E-E′, F-F′ and G-G′ in FIG. 16C. In some embodiments, the gate structures 125 wrap around the second semiconductor layers 54A, 54B and 54C. The source/drain epitaxial structures 100S/100D are formed at opposite sides of the gate structure 125. Furthermore, the source/drain contacts 130 are formed at opposite sides of the gate structure 125.

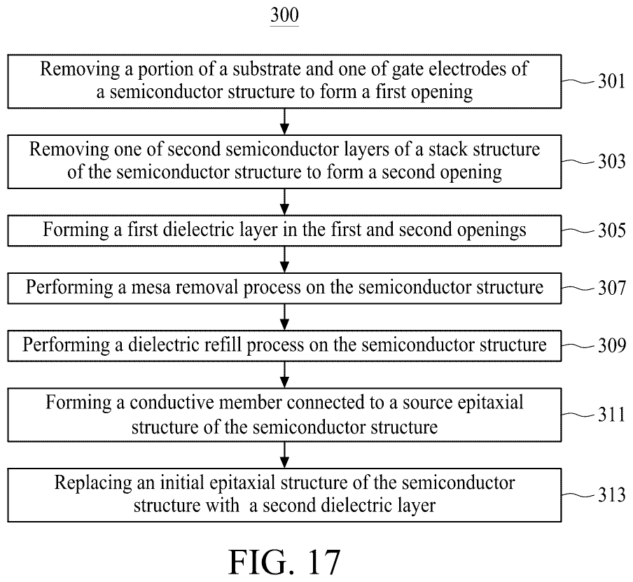

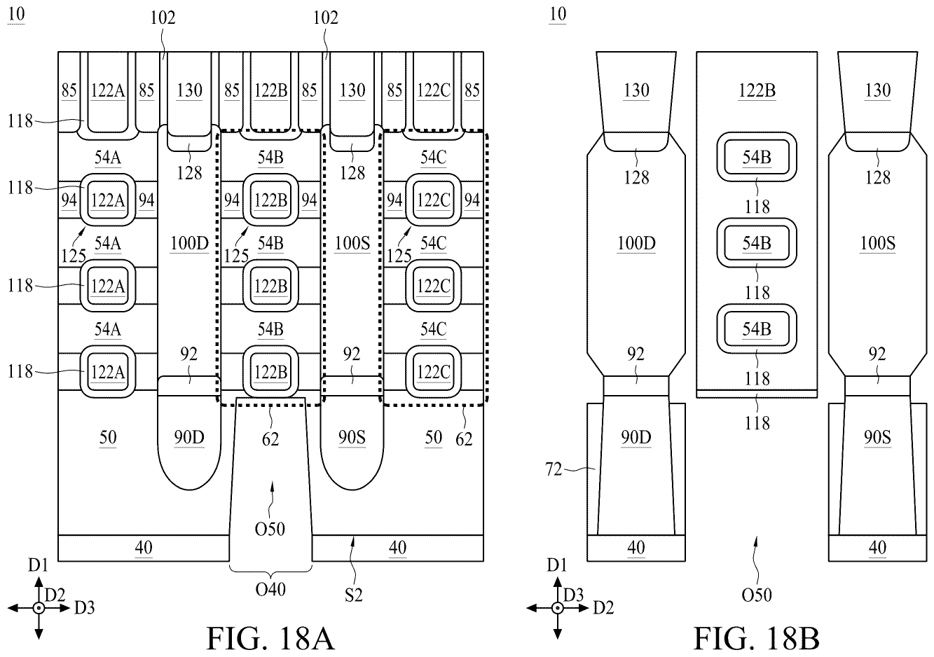

FIG. 17 is a flow diagram showing a method 300 for continuing the method 200 of forming the semiconductor structure 10 in FIGS. 16C and 16D. FIGS. 18A, 18B, 19A, 19B, 20A, 20B, 21A, 21B, 22A, 22B to 22D, 23A, 23B, 24A, 24B, 25A, 25B, 26A, 26B, 27A, 27B, 28A, 28B, 29A, 29B, 30A, 30B, 31A, 31B and 32A to 32C are schematic cross-sectional views illustrating sequential operations of the method 300 in FIG. 17. The cross-sectional views may be taken along different directions and along different lines or planes. The method 300 includes a number of operations and the description and illustration are not deemed as a limitation to the sequence of the operations.

In operation 301 of FIG. 17, portions of the substrate 50 and the gate electrode 122B are removed, as shown in FIGS. 18A, 18B, 19A, 19B, 20A, 20B, 21A and 21B. In some embodiments, the semiconductor structure 10 is flipped for subsequent operations; however, for ease of understanding, the figures do not show the semiconductor structure 10 as flipped.

Referring to FIGS. 18A and 18B, in some embodiments, a patterned photoresist 40 is formed on the second surface S2 of the substrate 50. The patterned photoresist 40 has one opening O40 or multiple separated openings O40, depending on design requirements. In some embodiments, the opening O40 is within a coverage of one of the fin structures 62. For example, the opening O40 is aligned with the fin structure 62 including the gate electrode 122B and the second semiconductor layers 54B. In some embodiments, multiple etching operations are performed on the second surface S2 of the substrate 50 using the patterned photoresist 40 as an etching mask. The etching operations may include dry etching, RIE, the like, or a combination thereof. In some embodiments, one etching operation is used to remove a portion of the substrate 50, and another etching operation is used to remove portions of the isolation region 72, but the present disclosure is not limited thereto. An order of the etching operations is not limited. The etching operations may be finished until the bottommost gate dielectric layer 118 is exposed through an opening O50. In some embodiments, the opening O50 tapers from the second surface S2 to the first surface S1. In some embodiments, the opening O50 is separated from the source/drain epitaxial structures 100S/100D.

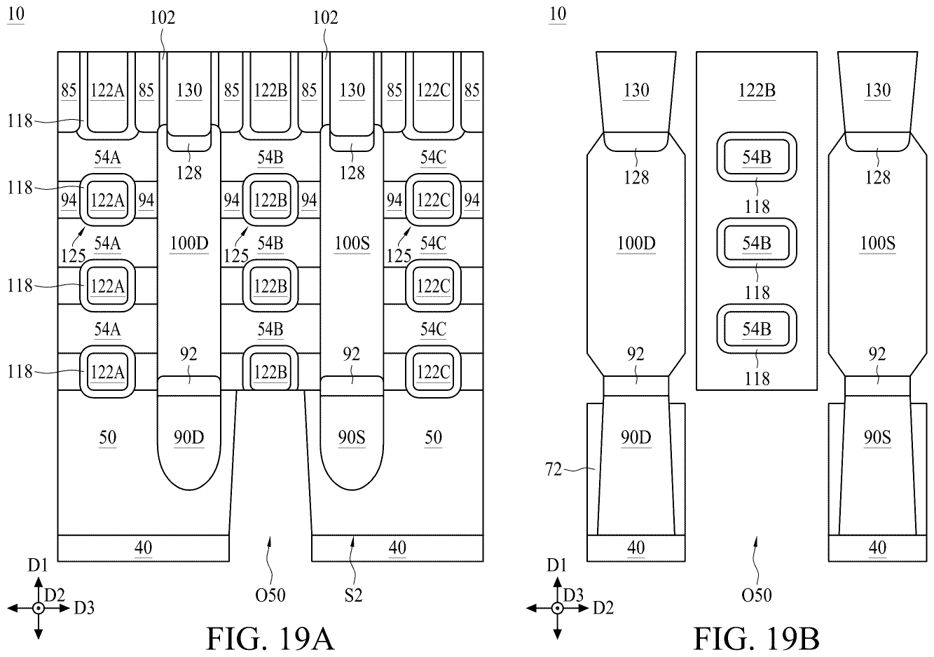

Referring to FIGS. 19A and 19B, in some embodiments, an etching operation is used to extend the opening O50 by removing a lower portion of the bottommost gate dielectric layer 118. The etching operation may include dry etching, RIE, the like, or a combination thereof. The etching operation enlarges the opening O50 and the gate electrode 122B is exposed through the enlarged opening O50.

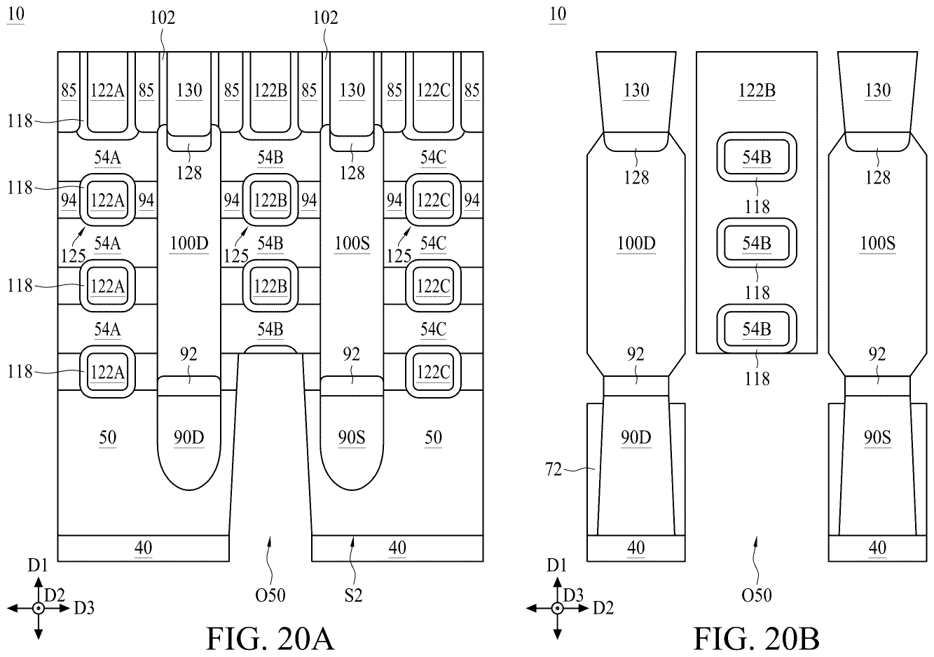

Referring to FIGS. 20A and 20B, in some embodiments, an etching operation is used to further extend the opening O50 by removing a portion of the gate electrode 122B. The etching operation may include dry etching, RIE, the like, or a combination thereof. The etching operation further enlarges the opening O50 and an upper portion of the bottommost gate dielectric layer 118 is exposed through the enlarged opening O50.

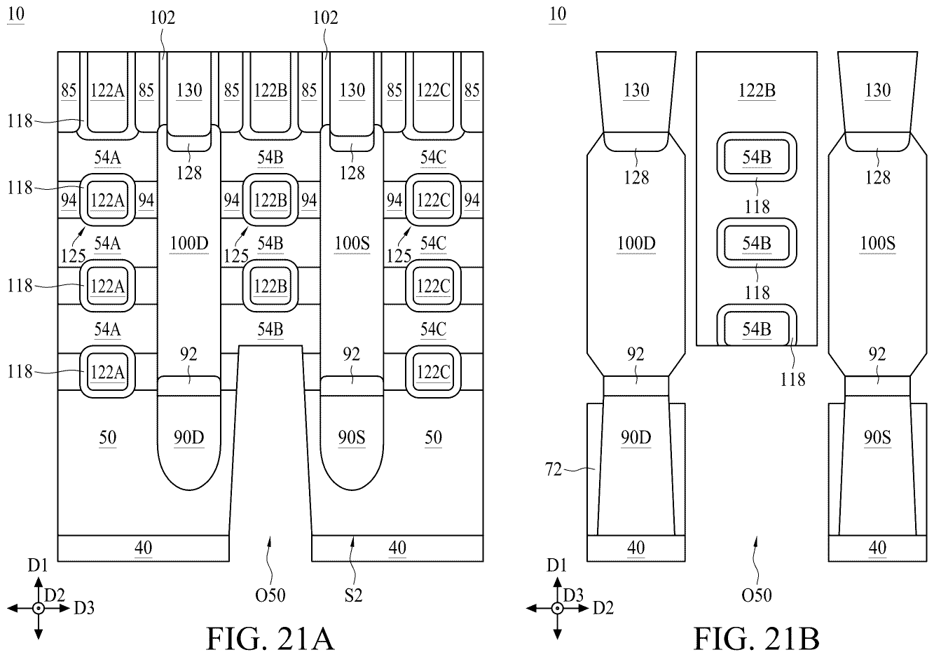

Referring to FIGS. 21A and 21B, in some embodiments, an etching operation is used to yet further extend the opening O50 by removing an upper portion of the bottommost gate dielectric layer 118. The etching operation may include dry etching, RIE, the like, or a combination thereof. The etching operation further enlarges the opening O50 and the bottommost second semiconductor layer 54B is exposed through the enlarged opening O50.

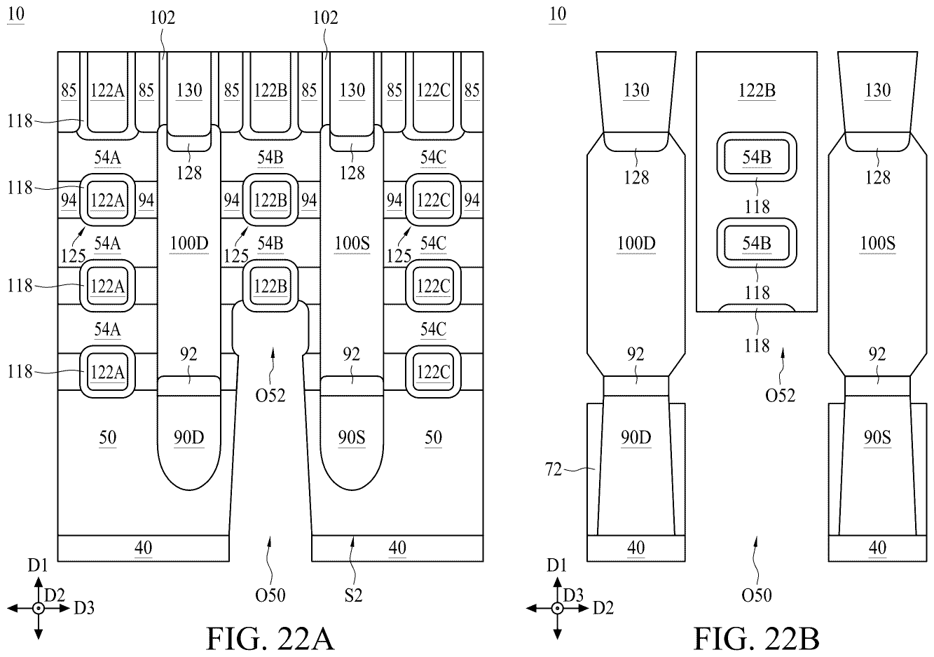

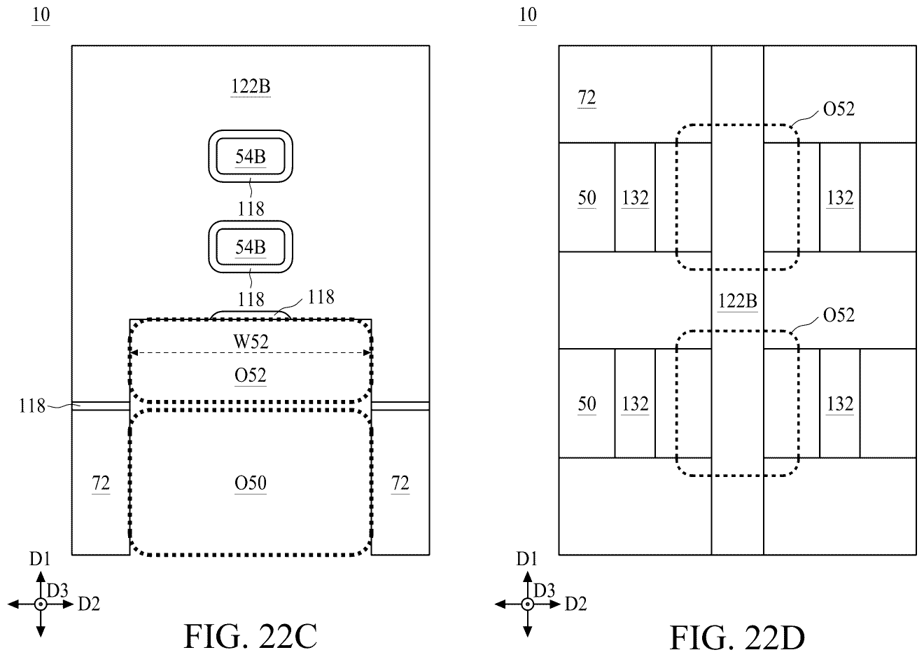

In operation 303 of FIG. 17, one of the second semiconductor layers 54B is removed, as shown in FIGS. 22A to 22D. Referring to FIGS. 22A and 22B, in some embodiments, an etching operation is used to remove the bottommost second semiconductor layer 54B through the opening O50. In some embodiments, the etching operation may include wet etching, atomic layer etching (ALE), lateral etching, the like, or a combination thereof. When the bottommost second semiconductor layer 54B is removed, an opening O52 is formed. The opening O52 is connected to the opening O50. The patterned photoresist 40 is then removed.

Referring to FIGS. 22C and 22D, FIG. 22C is a cross-sectional view along a direction same as a direction of FIG. 22B, and FIG. 22D is a top view of FIG. 22C. In some embodiments, during the removal of the bottommost second semiconductor layer 54B, portions of the gate electrode 122B and the substrate 50 are further removed using an additional etching operation. As such, a width W52 of the opening O52 can be increased, depending on design requirements. In some embodiments, the width W52 of the opening O52 is substantially uniform. Since the gate electrode 122B and the substrate 50 are both conductors, removal of portions of conductors in the semiconductor structure 10 can reduce parasitic capacitance that may be generated when the semiconductor structure 10 is in operation. FIG. 22D shows portions O52 of the gate electrode 122B from a top-view perspective that can be further removed to reduce the parasitic capacitance. In FIG. 22D, M0 metal lines 132 that may be subsequently formed over and electrically connected to the source/drain contacts 130.

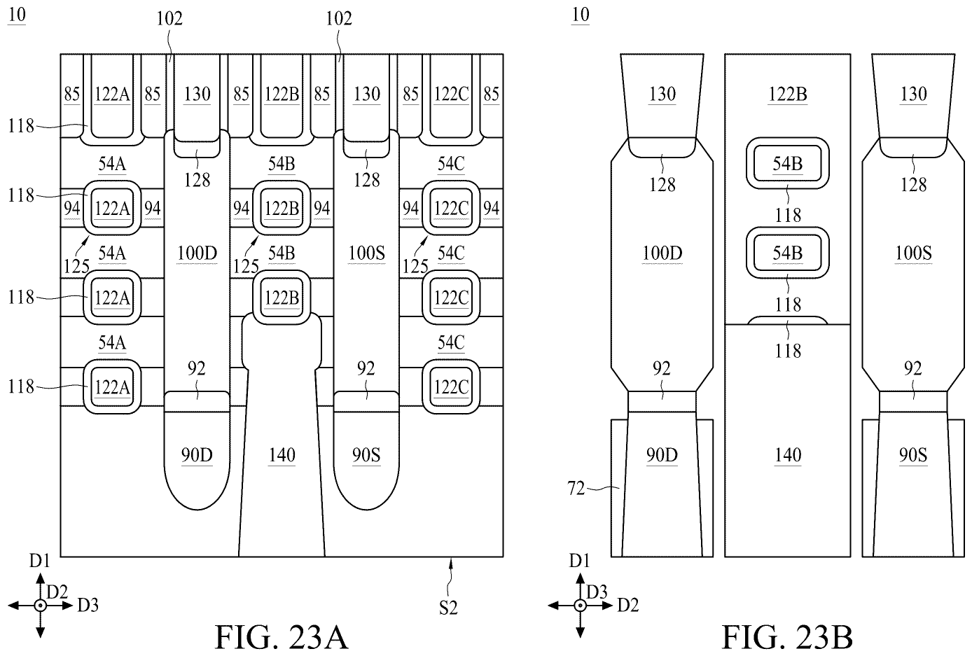

In operation 305 of FIG. 17, a dielectric layer 140 is formed in the openings O50 and O52, as shown in FIGS. 23A and 23B. The dielectric layer 140 may be formed using CVD, PECVD, FCVD, spin coating, or another suitable method. In some embodiments, the dielectric layer 140 is formed of a dielectric material such as silicon oxide, silicon nitride, silicon oxynitride, silicon oxycarbonitride, silicon carbon nitride, silicon carbide, the like, or a combination thereof. The dielectric material is deposited on the second surface S2 of the substrate 50 until the openings O50 and O52 are completely filled with the dielectric material. A planarization operation such as CMP may be used to planarize the dielectric material, thus forming the dielectric layer 140.

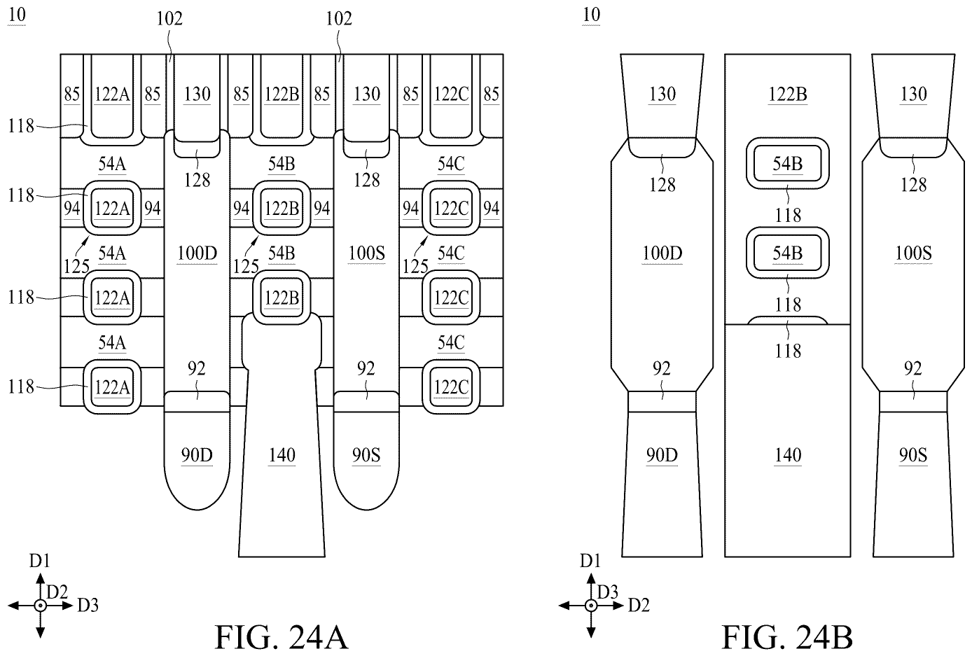

In operation 307 of FIG. 17, a mesa removal operation is performed on the semiconductor structure 10, as shown in FIGS. 24A and 24B. In some embodiments, the mesa removal operation refers to a complete removal of the substrate 50 and optionally the isolation region 72. In some embodiments, multiple etching operations are performed on the second surface S2 of the substrate 50. In such embodiments, etchants of the etching operations are selective to materials of the substrate 50 and the isolation region 72. The etching operations may include dry etching, RIE, the like, or a combination thereof. For example, one etching operation is used to remove the substrate 50, and another etching operation is used to remove the isolation region 72, but the present disclosure is not limited thereto. An order of the etching operations is not limited. After the mesa removal operation, the bottommost gate dielectric layers 118 and the initial epitaxial structures 90S/90D are exposed.

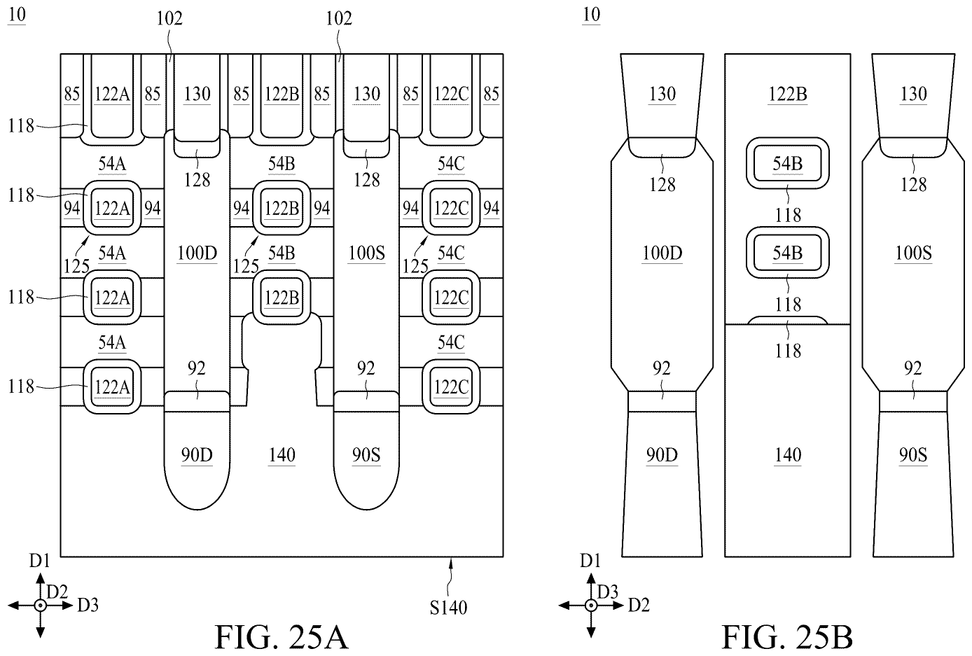

In operation 309 of FIG. 17, a dielectric refill operation is performed on the semiconductor structure 10, as shown in FIGS. 25A and 25B. In some embodiments, more dielectric materials of the dielectric layer 140 are deposited in areas where the substrate 50 was originally present. As such, the dielectric material covers the bottommost gate dielectric layers 118 and the initial epitaxial structures 90S/90D. A planarization operation such as CMP may be used to planarize the dielectric material. The resulting dielectric layer is also labeled 140 for convenience. The dielectric layer 140 may have a substantially flat surface S140.

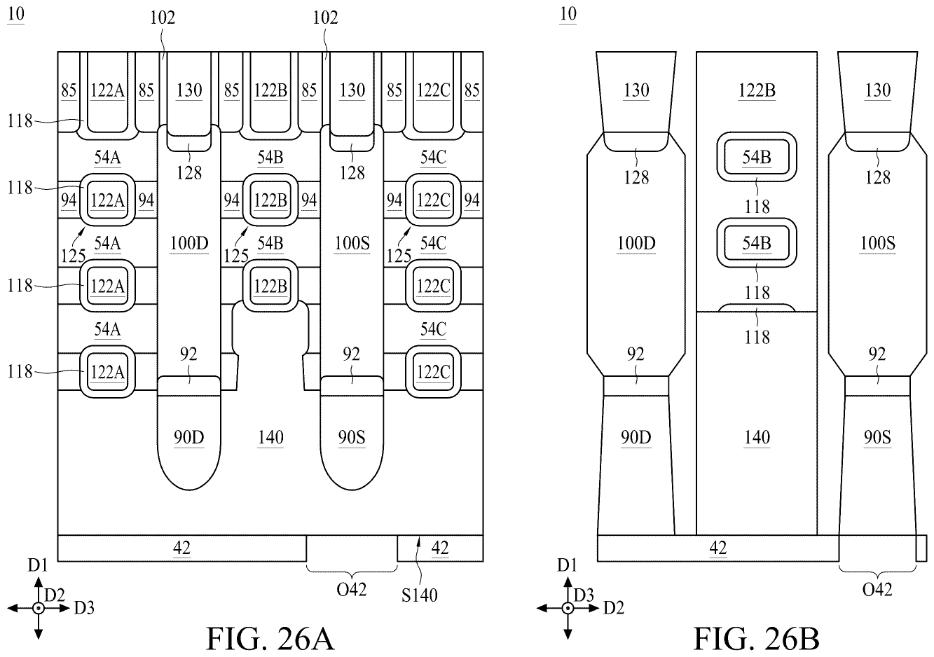

In operation 311 of FIG. 17, a conductive member 152 is formed connected to the source epitaxial structure 100S (or the source epitaxial structure 100D, but the present disclosure only uses the source epitaxial structure 100S as an example), as shown in FIGS. 26A, 26B, 27A, 27B, 28A, 28B, 29A, 29B, 30A and 30B. Referring to FIGS. 26A and 26B, a patterned photoresist 42 is formed on the surface S140 of the dielectric layer 140. The patterned photoresist 42 has one opening O42 or multiple separated openings O42, depending on. In some embodiments, the opening O42 is aligned with the source epitaxial structure 100S from a top-view perspective.

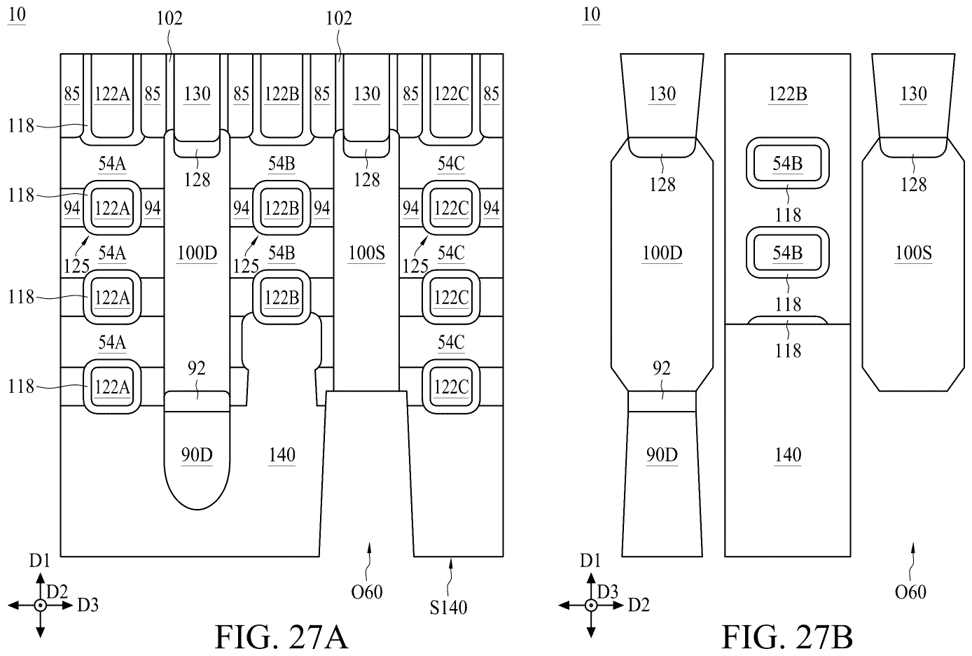

Referring to FIGS. 27A and 27B, one or more etching operations are performed on the surface S140 of the dielectric layer 140 using the patterned photoresist 42 as an etching mask. The etching operations may include dry etching, RIE, the like, or a combination thereof. In some embodiments, one etching operation is used to remove a portion of the dielectric layer 140 within a coverage of the source epitaxial structure 100S, and another etching operation is used to remove the initial epitaxial structure 90S and the dielectric layer 92 over the initial epitaxial structure 90S, but the present disclosure is not limited thereto. The etching operations may be finished until the source epitaxial structure 100S is exposed by an opening O60.

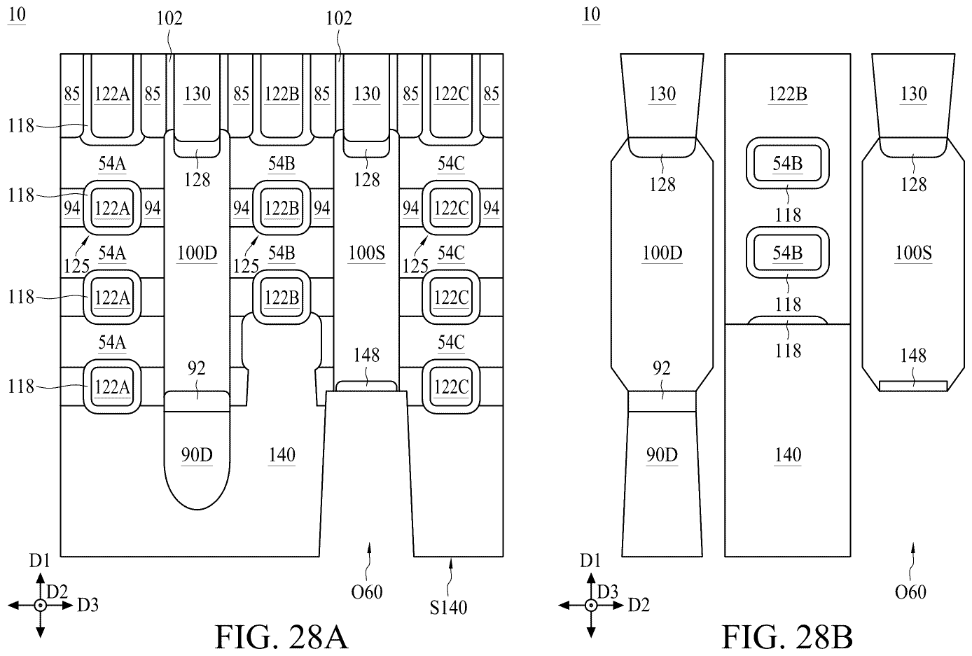

Referring to FIGS. 28A and 28B, a silicidation operation is performed on the source epitaxial structure 100S. In some embodiments, the silicidation operation converts a lower portion of the source epitaxial structure 100S into a silicide 148. The silicide 148 is used to improve adhesion or electrical conductivity between the source epitaxial structure 100S and a subsequently-deposited conductive material.

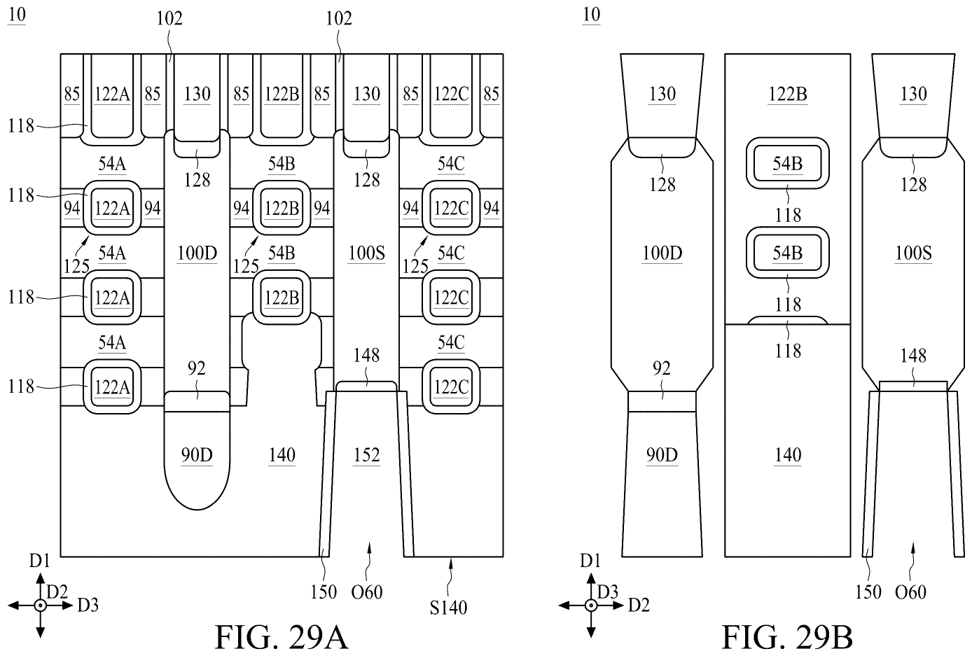

Referring to FIGS. 29A and 29B, a liner layer 150 is conformally formed in the opening O60. In some embodiments, the liner layer 150 is formed by CVD, ALD, or another suitable method. In some embodiments, the liner layer 150 includes silicon oxide, silicon nitride, silicon oxynitride, silicon oxycarbonitride, silicon carbon nitride, silicon carbide, the like, or a combination thereof. Although not specifically shown, one or more barrier layers may be formed on the liner layer 150. The barrier layer is made of titanium, tantalum, titanium nitride, tantalum nitride, the like, or a combination thereof.

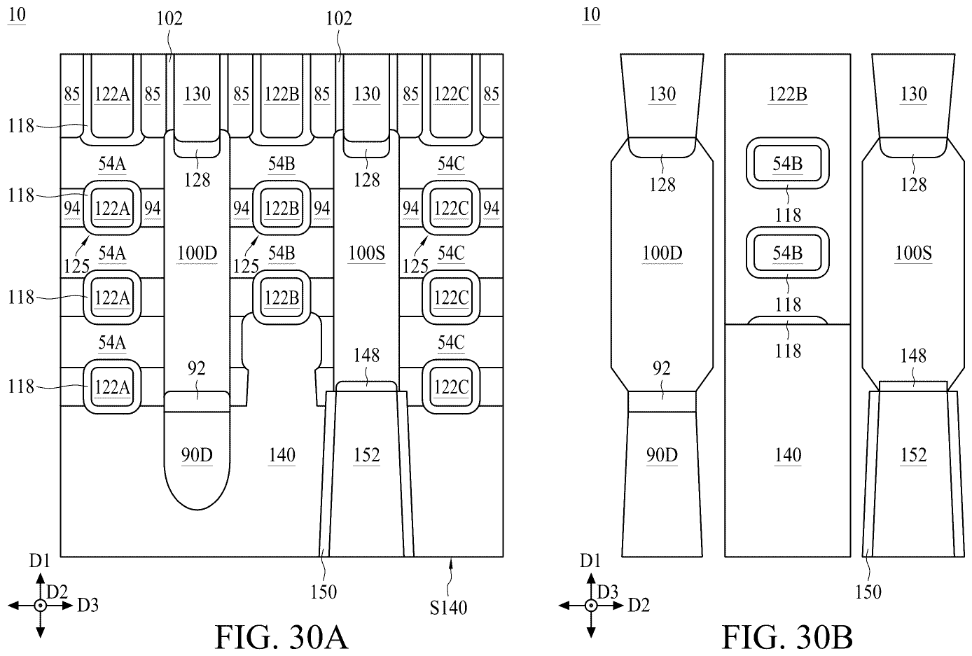

Referring to FIGS. 30A and 30B, one or more conductive materials are deposited into the opening O60 and over the liner layer 150. The conductive material includes W, Cu, Co, Al, Ni, Ta, Ti, Mo, Pd, Pt, Ru, Ir, Ag, Au, the like, or a combination thereof. A planarization operation such as CMP may be used to remove excess conductive material, thus forming the conductive member 152. The conductive member 152 is electrically connected to the source epitaxial structure 100S accordingly. According to some embodiments, the conductive member 152 is a conductive via.

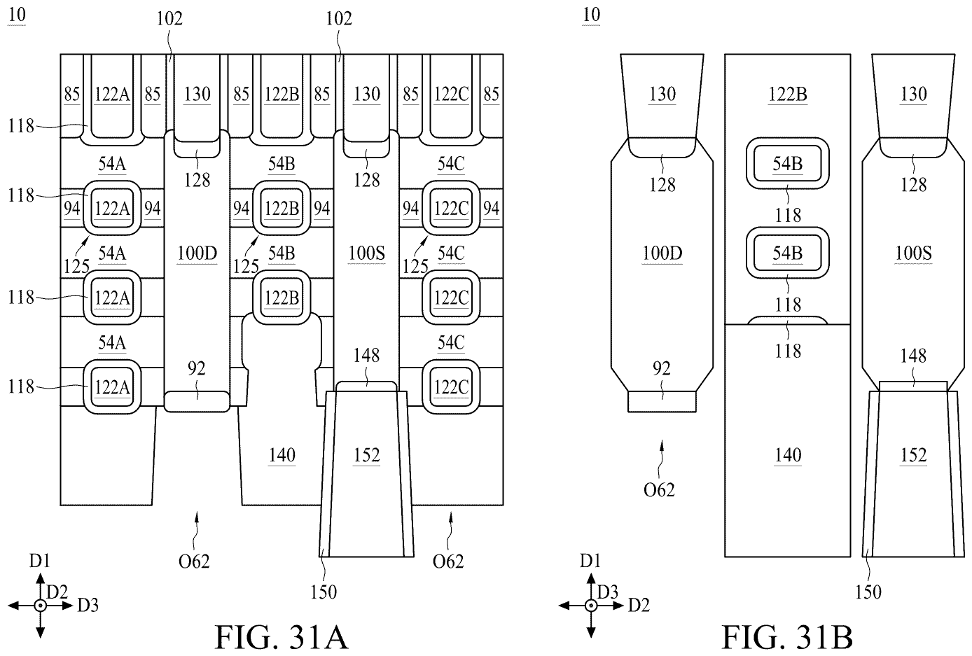

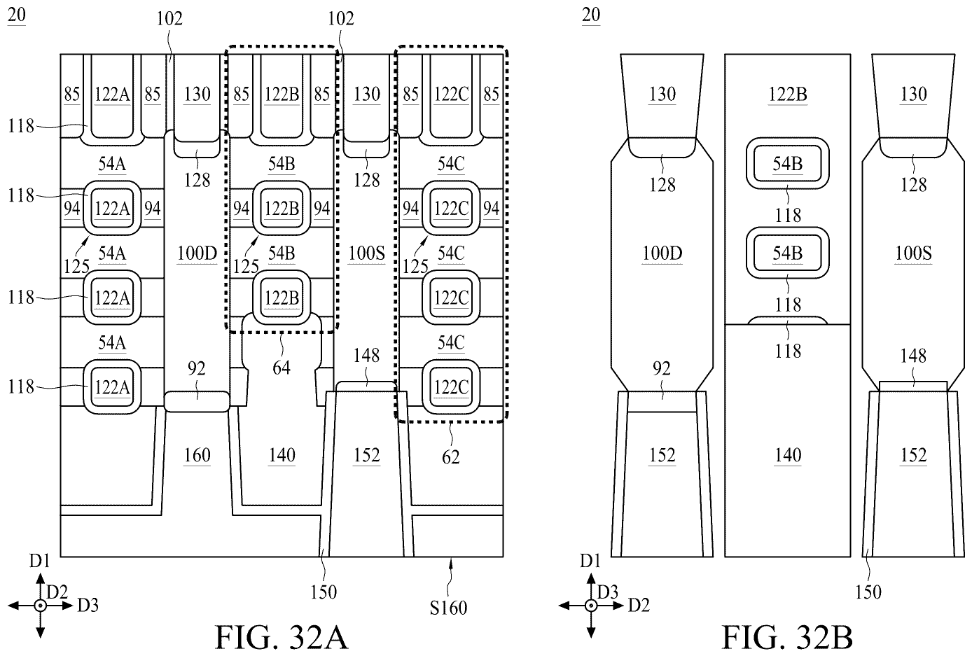

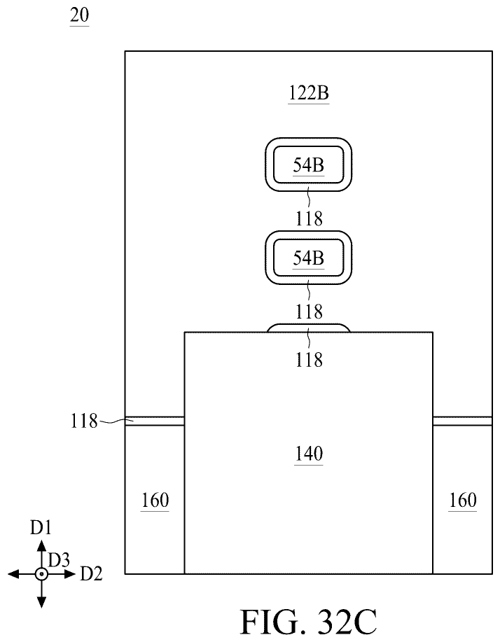

In operation 313 of FIG. 17, the initial epitaxial structure 90D is replaced with a dielectric layer 160, as shown in FIGS. 31A, 31B and 32A to 32C. Referring to FIGS. 31A and 31B, one or more etching operations are performed on the surface S140 of the dielectric layer 140. The etching operations may include dry etching, RIE, the like, or a combination thereof. In some embodiments, one etching operation is used to remove portions of the dielectric layer 140, and another etching operation is used to remove the initial epitaxial structure 90D and the dielectric layer 92 over the initial epitaxial structure 90D, but the present disclosure is not limited thereto. The etching operations may be finished until the drain epitaxial structure 100D is exposed. As such, multiple openings O62 are formed. In some embodiments, the drain epitaxial structure 100D is exposed by one of the openings O62.

Referring to FIGS. 32A and 32B, a dielectric material is deposited into the openings O62 using, for example, CVD, ALD, or another suitable method. The dielectric material may be silicon oxide, silicon nitride, SiON, FSG, PSG, BSG, BPSG, USG, the like, or a combination thereof. A planarization operation such as CMP may be used to planarize the dielectric material, thus forming the dielectric layer 160. At this stage, a semiconductor structure 20 is formed. In some embodiments, the semiconductor structure 20 is formed using the method 200 in FIG. 1, followed by the method 300 in FIG. 17. In some embodiments, a backside-power delivery (BPD) is used to provide power to the semiconductor structure 20 through the conductive member 152. The conductive member 152 may be referred to as a backside via or backside power rail (BPR). The dielectric layer 160 may be referred to as a backside interlayer dielectric (B-ILD) layer. In some embodiments, when the conductive member 152 is electrically connected to a power supply, the liner layer 150 is used for preventing short circuit when current flows through the conductive member 152.

Referring to FIG. 32C, in embodiments where portions of the gate electrode 122B and the substrate 50 are further removed, a space thus generated is filled with more dielectric materials to form the dielectric layer 140.

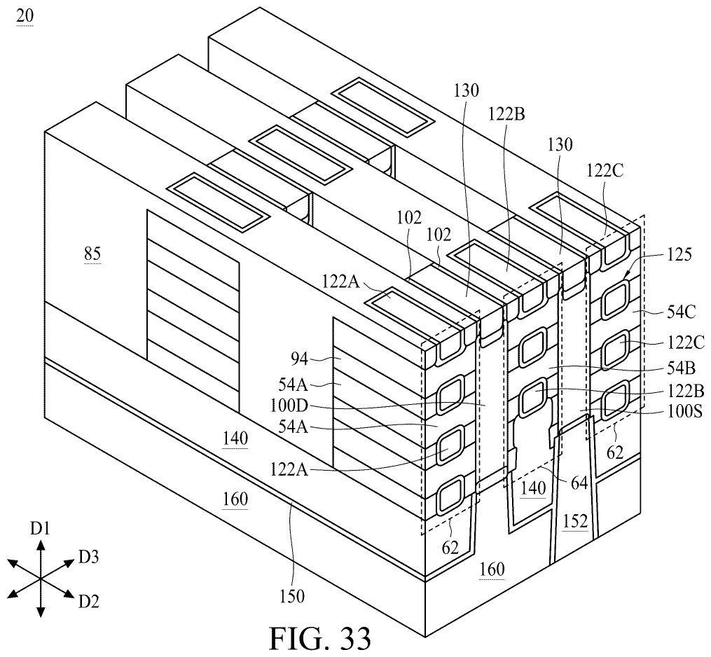

FIG. 33 is a schematic perspective view of the semiconductor structure 20. In some embodiments, the semiconductor structure 20 includes fin structures with different numbers of channel regions (nanosheets). In some embodiments, the fin structure 62 has N second semiconductor layers such as the second semiconductor layers 54A or 54C, and the fin structure 64 has N-1 second semiconductor layers such as the second semiconductor layers 54B. In such embodiments, the fin structure 62 has N nanosheets, and the fin structure 64 has N-1 nanosheets. The fin structure 64 includes one fewer nanosheet than the fin structure 62. The semiconductor structure 20 may be referred to as a hybrid-sheet structure including both N-1 nanosheets and N nanosheets. In some embodiments, the semiconductor structure 20 includes a hybrid-sheet structure including K nanosheets and N nanosheets, where K is not equal to N. Furthermore, the fin structure 62 includes M gate structures 125 between the N nanosheets, and the fin structure 64 includes M-1 gate structures 125 between the N-1 nanosheets. That is, the fin structure 64 includes one fewer metal gate than the fin structure 62. The fin structure 62 and the fin structure 64 may be adjacent to each other or distal from each other, e.g., in different cells or regions of a common semiconductor structure, depending on design requirements. In some embodiments, the fin structure 62 and the fin structure 64 are separated by one source epitaxial structure 100S or one drain epitaxial structure 100D. In other embodiments, the fin structure 62 and the fin structure 64 are separated by multiple source/drain epitaxial structures 100S/100D.

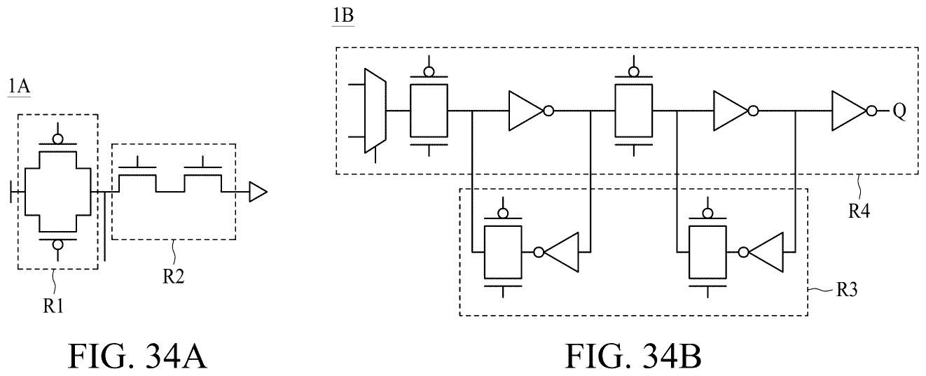

FIGS. 34A and 34B are simplified circuit diagrams of semiconductor devices 1A and 1B, respectively, including one or more of the semiconductor structures 20 in FIG. 33. The semiconductor device 1A includes a first circuit R1 connected to a second circuit R2. According to some embodiments, the semiconductor device 1A includes a critical path in the second circuit R2. To seek a better tradeoff between power and speed, the transistors for forming the critical path or the transistors in the second circuit R2 are implemented using the fin structure 62, while the transistors in the first circuit R1 are implemented using the fin structure 64. That is because, on one hand, the transistors implemented using the fin structure 62 include a greater number of channel regions than that of the fin structure 64, and thus the transistors implemented using the fin structure 62 can have a greater channel current to achieve a greater operation speed than that of the transistors implemented using the fin structure 64. The operation speed of the speed-sensitive critical path can be increased by help of the fin structure 62, and the overall speed of the semiconductor device 1A can be improved accordingly. Thus, the fin structure 62 is suitable to be used in the second circuit R2. On the other hand, transistors implemented using the fin structure 64 can have less channel current than the fin structure 62 to save more power than that of the transistors implemented using the fin structure 64 without significantly affecting the operation speed of the semiconductor device 1A and is thus suitable to be used in the first circuit R1. That is, the semiconductor device 1A includes some transistors with a greater number of channel regions (nanosheets) and some transistors with a less number of channel regions (nanosheets), and thus a better compromise between the speed and power can be achieved for the semiconductor device 1A. Therefore, the semiconductor device 1A has a hybrid-sheet fin structure.

Similarly, the semiconductor device 1B includes a third circuit R3 connected to a fourth circuit R4. In some embodiments, the first circuit R1 includes one or more fin structures 64, and the second circuit R2 includes one or more fin structures 62. According to some embodiments, the semiconductor device 1B includes a critical path in the second circuit R3. To seek a better tradeoff between power and speed, the transistors for forming the critical path or the transistors in the third circuit R3 are implemented using the fin structure 62, while the transistors in the fourth circuit R4 are implemented using the fin structure 64. As a result, the semiconductor device 1B includes some transistors with a greater number of channel regions (nanosheets) and some transistors with a less number of channel regions (nanosheets), and thus a better compromise between the speed and power can be achieved for the semiconductor device 1B. Therefore, the semiconductor device 1A has a hybrid-sheet fin structure. Therefore, the semiconductor device 1B has a hybrid-sheet fin structure.

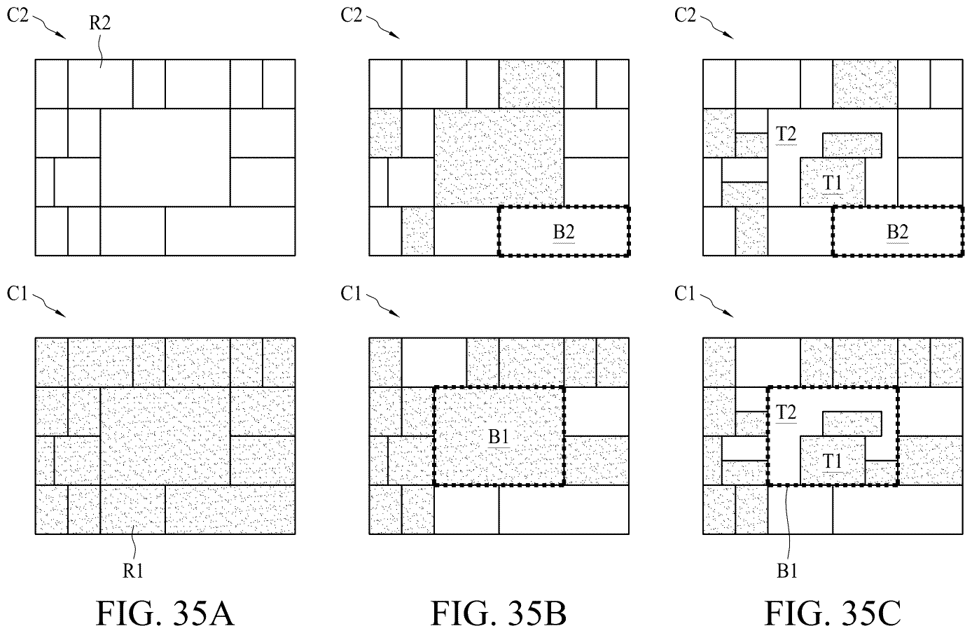

FIGS. 35A to 35C are schematic views of chips or semiconductor structures including the semiconductor device 1A in FIG. 34A or the semiconductor device 1B in FIG. 34B. The semiconductor device 1A or 1B includes one or more first chips C1 and one or more second chips C2. The first chip C1 may be a system on a chip (SoC), and the second chip C2 may be a central processing unit (CPU) chip, but the present disclosure is not limited thereto.

Referring to FIG. 35A, in some embodiments, an arrangement of separating the fin structures 64 (with a less number of nanosheets) and the fin structures 62 (with a greater number of nanosheets) is based on different chips or cells. In some embodiments, the first chip C1 includes only circuits with characteristics similar to the first circuit R1 or the fourth circuit R4, each of which including transistors implemented with the fin structure 64, and the second chip C2 includes only circuits with characteristics similar to the second circuit R2 or the third circuit R3, each of which including the fin structure 62. That is, the first chip C1 includes only transistors with a less number, e.g., N-1, of channel regions, and the second chip C1 includes only transistors with a greater number, e.g., N, of channel regions.

Referring to FIG. 35B, in some embodiments, an arrangement of separating the fin structures 64 (with a less number of nanosheets) and the fin structures 62 (with a greater number of nanosheets) is based on different circuit blocks of the chips or cells. In some embodiments, the first chip C1 and the second chip C2 respectively include multiple circuit blocks B1 and B2. The circuit blocks B1 of the first chip C1 include circuits with fin structures 64, similar to the first circuit R1, and the circuit blocks B2 of the first chip C1 includes circuits with fin structures 62, similar to the second circuit R2. Likewise, the blocks B1 of the second chip C2 include circuits with fin structures 64, similar to the first circuit R1, and the blocks B2 of the second chip C2 include circuits with fin structures 62, similar to the second circuit R2. In other words, the transistors in each circuit block B1 or B2 of the first chip C1 or the second chip C2 are implemented with all the fin structure 62 or with all the fin structure 64.

Referring to FIG. 35C, in some embodiments, an arrangement of separating the fin structures 64 (with N-1 nanosheets) and the fin structures 62 (with a greater number of nanosheets) is based on different transistors. In some embodiments, a single block B1 or B2 of the first chip C1 or the second chip C2 includes multiple transistors T1 and T2. In some embodiments, the transistor T1 includes the fin structure 62, and the transistor T2 includes the fin structure 64. In such embodiments, immediately adjacent or closely arranged transistors may include different numbers of channel regions (nanosheets). In other embodiments, the first chip C1 or the second chip C2 includes transistors with the fin structure 62 and transistors with the fin structure 64 in a single block B1 of the first chip C1 or the second chip C2.

Capacitance is a measure of the ability to store electric charges. Parasitic capacitance is an unavoidable and usually unwanted capacitance that exists between parts of an electronic component or circuit because of their proximity to each other. When two conductive or semiconductive materials are insulated from while arranged close to each other, an electric field between them can be generated to cause electric charge to accumulate on them through an insulating material interposed between the two conductive or semiconductive materials.

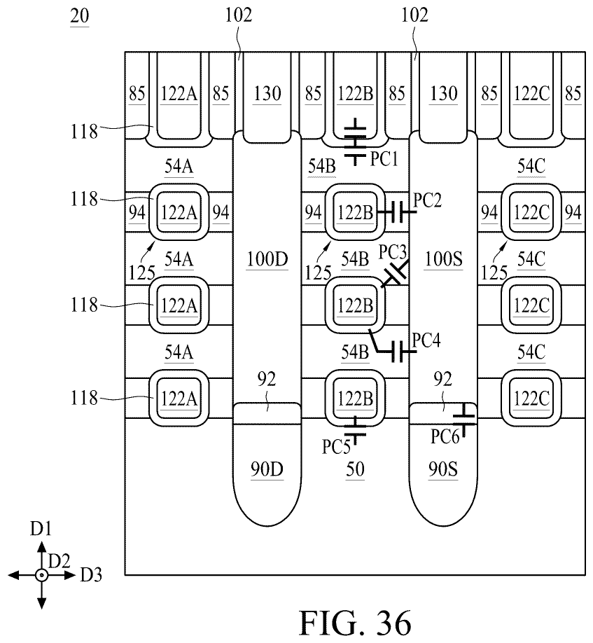

FIG. 36 is a schematic view showing possible locations where parasitic capacitance may exist in a uniform-sheet nanosheet semiconductor structure similar to the semiconductor structure 10 shown in FIG. 16C. A first parasitic capacitance PC1 may exist between the gate electrodes 122A, 122B, 122C between the gate spacers 85 and the channel regions 54A, 54B, 54C or the gate electrodes 122A, 122B and 122C adjacent to the source epitaxial structure 100S or the drain epitaxial structure 100D. A second parasitic capacitance PC2 may exist between the gate electrodes 122A, 122B, 122C, which are between the source epitaxial structure 100S and the drain epitaxial structure 100D, and the adjacent source epitaxial structure 100S or the drain epitaxial structure 100D through the interposed inner spacers 94. A third parasitic capacitance PC3 may exist between a lightly doped region (not separately shown), which are on two ends of the channel regions 54A, 54B, 54C near the source epitaxial structure 100S and the drain epitaxial structure 100D, and the adjacent gate electrodes 122A, 122B and 122C. A fourth parasitic capacitance PC4 may exist between the gate electrodes 122A, 122B, 122C, which are between the source epitaxial structure 100S and the drain epitaxial structure 100D, and the adjacent source epitaxial structure 100S or the drain epitaxial structure 100D through the interposed channel regions 54A, 54B, 54C. A fifth parasitic capacitance PC5 may exist between the gate electrodes 122A, 122B, 122C, which are between the source epitaxial structure 100S and the drain epitaxial structure 100D, and the underlying substrate 50. A sixth parasitic capacitance PC6 may exist between the source epitaxial structure 100S or the drain epitaxial structure 100D, and the underlying substrate 50 or the initial epitaxial structures 90D, 90S through the dielectric layer 92.

Referring to FIG. 32A, where the proposed hybrid-sheet semiconductor structure 20 is different from the uniform-sheet semiconductor structure 10 shown in FIG. 16C in that the bottommost gate electrode 122B closest to the substrate 50 and its adjacent channel region 54B are removed and replaced by the dielectric layer 140. Further, the substrate 50 is also replaced by the dielectric layer 140. Due to the removal of the abovementioned gate electrode 122B, channel region 54B and the substrate 50, the amounts of the first, second, third, fourth, fifth and sixth parasitic capacitances PC1, PC2, PC3, PC4, PC5 and PC6, respectively, can be reduced. According to some embodiments, given that the total number of the channel numbers of the uniform-sheet semiconductor structure 10 is set as three, the reduction amount of the parasitic capacitance of the first and second parasitic capacitances PC1 and PC2 for the proposed hybrid-sheet semiconductor structure 20 can reach as much as ⅓. Further, according to some embodiments, given that the total number of the channel numbers of the uniform-sheet semiconductor structure 10 is set as three, the reduction amount of the parasitic capacitance of the third and fourth parasitic capacitances PC3 and PC4 for the proposed hybrid-sheet semiconductor structure 20 can reach less than about ⅓. According to some embodiments, the parasitic capacitance of the fifth and sixth parasitic capacitances PC5 and PC6 for the proposed hybrid-sheet semiconductor structure 20 is substantially eliminated due to the removal of the substrate 50. Therefore, the proposed hybrid-sheet semiconductor structure 20 can improve power efficiency by reducing the power consumption caused by the parasitic capacitances.

The present disclosure proposes a semiconductor structure with capacitance hybrid-sheet configuration and a method for forming such semiconductor structure. The proposed hybrid-sheet configuration can provide advantages. The parasitic capacitance is decreased significantly due to removal of electrical conductive and semiconductive materials. For example, when a substrate or one of metal gates is removed, parasitic capacitance of the semiconductor structure is reduced. Additionally, the nanosheet semiconductor structures provide design flexibility for fin structures with different numbers of nanosheets (channel numbers). As such, the speed-sensitive circuit can be implemented with the fin structure having a greater number of channel numbers to improve speed, while the power-sensitive circuit can be implemented with the fin structure having a less number of channel numbers to save power. A better power-speed tradeoff can be achieved and the system performance can be enhanced without sacrificing much power. Therefore, power efficiency of the semiconductor structure can be further improved. Furthermore, the formation of the backside power rail can be performed during the removal of the substrate. Therefore, the manufacturing time and cost can be managed in a more economical manner. Moreover, the removal operation of the gate electrode, the channel region and the substrate is performed from the second surface (backside) of the semiconductor structure. The layout and circuit design of the semiconductor structure on the first surface (front side) is kept unchanged. Thus, the original well-proven circuit layout on the front side can be reused in the design of the proposed semiconductor structure. The design cycle and cost can be further reduced.

One aspect of the present disclosure provides a method of forming a semiconductor structure. The method includes: providing a substrate including a first surface and a second surface opposite to the first surface; forming an isolation region over the first surface, wherein the isolation region includes an insulating material with a dielectric constant between about 3 and about 5; forming a first stack structure and a second semiconductor stack structure protruding from the first surface, wherein the first stack structure includes a plurality of first sheets and the second stack structure includes a plurality of second sheets; forming a first gate structure and a second gate structure over the first stack structure and the second stack structure, wherein the first gate structure and the second gate structure wrap around the plurality of first sheets and the plurality of second sheets, respectively; forming a first epitaxial structure and a second epitaxial structure in recesses of the substrate on opposite sides of the second stack structure; forming etch stop layers over the respective first and second epitaxial structures; forming dielectric layers over the respective etch stop layers; forming a first opening by recessing the substrate from the second surface; and filling the first opening with a first dielectric material.

Another aspect of the present disclosure provides a method of forming a semiconductor structure. The method includes: providing a substrate including a first surface and a second surface opposite to the first surface; forming an isolation structure over the first surface; forming a first stack structure and a second stack structure protruding from the first surface, wherein the first stack structure includes first sacrificial layers and first channel layers alternatingly arranged with the first sacrificial layers, and the second stack structure includes second sacrificial layers and second channel layers alternatingly arranged with the second sacrificial layers; forming a first epitaxial structure and a second epitaxial structure in recesses of the substrate on opposite sides of the first stack structure, wherein the first epitaxial structure is between the first stack structure and the second stack structure, and portions of the first and second epitaxial structures overhang the isolation structure; forming a first source/drain epitaxial structure over the first epitaxial structure and a second source/drain epitaxial structure over the second epitaxial structure; converting upper portions of the first and second source/drain epitaxial structures into metal silicides; forming source/drain contacts on the respective silicides and electrically coupled to the first and second source/drain epitaxial structures, respectively; replacing the first sacrificial layers and the second sacrificial layers with a first dielectric layer and a conductive layer; forming a first opening by etching the substrate and a conductive layer, closest to the second surface, of the first stack structure from the second surface, wherein the first opening is between the first epitaxial structure and the second epitaxial structure; forming a second opening by etching through a bottommost one of the first channel layers through the first opening, wherein the second opening is connected to the first opening; and filling the first opening and the second opening with a first dielectric material.

Yet another aspect of the present disclosure provides a semiconductor structure. The semiconductor structure includes: a first stack structure including first metal gate structures and first channel layers alternatingly arranged with the first metal gate structures; a second stack structure separated from the first stack structure and including second metal gate structures and second channel layers alternatingly arranged with the second metal gates; a drain epitaxial structure and a source epitaxial structure disposed on opposite sides of the first stack structure, wherein the drain epitaxial structure is between the first stack structure and the second stack structure, and the source epitaxial structure is on one side of the second stack structure opposite to the drain epitaxial structure; a first contact etch stop layer disposed over the drain epitaxial structure and a second contact etch stop layer disposed over the source epitaxial structure; a first dielectric layer disposed over the first contact etch stop layer and a second dielectric layer disposed over the second contact etch stop layer; a drain contact extending through the first dielectric layer and electrically coupled to the drain epitaxial structure; a source contact extending through the second dielectric layer and electrically coupled to the source epitaxial structure. The first stack structure has a first number of the first channel layers, the second stack structure has a second number of the second channel layers, and the first number is different from the second number.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a semiconductor structure, comprising:
providing a substrate including a first surface and a second surface opposite to the first surface;
forming an isolation region over the first surface, wherein the isolation region includes an insulating material with a dielectric constant between about 3 and about 5;
forming a first stack structure and a second semiconductor stack structure protruding from the first surface, wherein the first stack structure includes a plurality of first sheets and the second stack structure includes a plurality of second sheets;
forming a first gate structure and a second gate structure over the first stack structure and the second stack structure, wherein the first gate structure and the second gate structure wrap around the plurality of first sheets and the plurality of second sheets, respectively;
forming a first epitaxial structure and a second epitaxial structure in recesses of the substrate on opposite sides of the second stack structure;
forming etch stop layers over the respective first and second epitaxial structures;
forming dielectric layers over the respective etch stop layers;
forming a first opening by recessing the substrate from the second surface; and
filling the first opening with a first dielectric material.

2. The method of claim 1, further comprising:
forming a first source/drain epitaxial structure and a second source/drain epitaxial structure over the first epitaxial structure and the second epitaxial structure, respectively, wherein the first and second source/drain epitaxial structures interfacing sidewalls of the second sheets.

3. The method of claim 2, wherein the first opening is between the first epitaxial structure and the second epitaxial structure.

4. The method of claim 2, wherein the first opening is separated from the first and second source/drain epitaxial structures.

5. The method of claim 2, further comprising:
removing the substrate to expose at least the first epitaxial structure, the second epitaxial structure and the first gate structure.

6. The method of claim 5, further comprising:
depositing a second dielectric material to cover the first epitaxial structure, the second epitaxial structure and the first gate structure.

7. The method of claim 6, further comprising:
removing a portion of the second dielectric material and the second epitaxial structure to form a second opening exposing the second source/drain structure; and
filling the second opening with a conductive material to form a conductive member.

8. The method of claim 7, further comprising:
removing a portion of the second dielectric material and the second epitaxial structure to form a second opening exposing the second source/drain structure;
conformally forming a liner layer in the second opening and along inner sidewalls of the second dielectric material; and
filling the second opening with a conductive material to form a conductive member.

9. The method of claim 1, further comprising:
forming a hole by removing a bottommost one of the second sheets exposed by the first opening,
wherein the first dielectric material further fills the hole.

10. A method of forming a semiconductor structure, comprising:
providing a substrate including a first surface and a second surface opposite to the first surface;
forming an isolation structure over the first surface;
forming a first stack structure and a second stack structure protruding from the first surface, wherein the first stack structure includes first sacrificial layers and first channel layers alternatingly arranged with the first sacrificial layers, and the second stack structure includes second sacrificial layers and second channel layers alternatingly arranged with the second sacrificial layers;
forming a first epitaxial structure and a second epitaxial structure in recesses of the substrate on opposite sides of the first stack structure, wherein the first epitaxial structure is between the first stack structure and the second stack structure, and portions of the first and second epitaxial structures overhang the isolation structure;
forming a first source/drain epitaxial structure over the first epitaxial structure and a second source/drain epitaxial structure over the second epitaxial structure;
converting upper portions of the first and second source/drain epitaxial structures into metal silicides;
forming source/drain contacts on the respective silicides and electrically coupled to the first and second source/drain epitaxial structures, respectively;
replacing the first sacrificial layers and the second sacrificial layers with a first dielectric layer and a conductive layer;
forming a first opening by etching the substrate and a conductive layer, closest to the second surface, of the first stack structure from the second surface, wherein the first opening is between the first epitaxial structure and the second epitaxial structure;
forming a second opening by etching through a bottommost one of the first channel layers through the first opening, wherein the second opening is connected to the first opening; and
filling the first opening and the second opening with a first dielectric material.

11. The method of claim 10, wherein the first opening exposes an inner spacer surrounding the conductive layer of the first stack nanostructure.

12. The method of claim 10, wherein the forming of the first opening comprises using dry etching or reactive ion etching (RIE), and the forming of the second opening includes using wet etching, atomic layer etching (ALE) or lateral etching.

13. The method of claim 10, wherein the first opening the first opening tapers from the second surface to the first surface, and the second opening has a substantially uniform width.

14. The method of claim 10, further comprising:
removing the substrate;
covering the first epitaxial structure, the second epitaxial structure and the first dielectric material with a second dielectric material;
removing a portion of the second dielectric material and the second epitaxial structure to form a third opening; and
filling the third opening with a conductive material to form a conductive member.

15. The method of claim 14, wherein the conductive member is electrically connected to the second source/drain structure.

16. A semiconductor structure, comprising:
a first stack structure including first metal gate structures and first channel layers alternatingly arranged with the first metal gate structures;
a second stack structure separated from the first stack structure and including second metal gate structures and second channel layers alternatingly arranged with the second metal gates;
a drain epitaxial structure and a source epitaxial structure disposed on opposite sides of the first stack structure, wherein the drain epitaxial structure is between the first stack structure and the second stack structure, and the source epitaxial structure is on one side of the second stack structure opposite to the drain epitaxial structure;
a first contact etch stop layer disposed over the drain epitaxial structure and a second contact etch stop layer disposed over the source epitaxial structure;
a first dielectric layer disposed over the first contact etch stop layer and a second dielectric layer disposed over the second contact etch stop layer;
a drain contact extending through the first dielectric layer and electrically coupled to the drain epitaxial structure;
a source contact extending through the second dielectric layer and electrically coupled to the source epitaxial structure, wherein
the first stack structure has a first number of the first channel layers,
the second stack structure has a second number of the second channel layers, and
the first number is different from the second number.

17. The semiconductor structure of claim 16, wherein the first number is equal to the second number minus one.

18. The semiconductor structure of claim 16, wherein a bottommost one of the first metal gate structures is at a level higher than a bottommost one of the second metal gate structures.

19. The semiconductor structure of claim 18, further comprising:
a conductive member electrically connected to the source structure from a side of the bottommost one of the first metal gate structures.

20. The semiconductor structure of claim 19, further comprising:
a third dielectric layer covering the bottommost one of the first metal gate structures and laterally surrounding the conductive member; and
a fourth dielectric layer covering the third dielectric layer and laterally surrounding the conductive member.
